(19) United States
(12) Patent Application Publication
(10) Pub. No.: US 2010/0308697 A1
(43) Pub. Date: Dec. 9, 2010

(54) METHOD OF MANUFACTURING PIEZOELECTRIC VIBRATOR, PIEZOELECTRIC VIBRATOR, OSCILLATOR, ELECTRONIC DEVICE, AND RADIO CLOCK

(76) Inventors: Kiyoshi ARATAKE, Chiba-shi (JP); Masashi NUMATA, Chiba-shi (JP)

Correspondence Address: Brinks Hofer Gilson & Lione/Seiko Instruments Inc., P.O. Box 10395, Chicago, IL, 60611, US

(21) Appl. No.: 12/858,314

(22) Filed: Aug. 17, 2010

Related U.S. Application Data
(63) Continuation of application No. PCT/JP2008/065551, filed on Aug. 29, 2008.

(30) Foreign Application Priority Data
Feb. 18, 2008 (JP) JP2008-036423

(51) Int. Cl. H01L 41/053; H01L 41/22

(52) U.S. Cl. 310/348; 29/25.35

(57) ABSTRACT

A piezoelectric vibrator includes a base substrate, a lid substrate, a piezoelectric vibrating reed, a pair of external electrodes, a pair of through electrodes, and routing electrodes. The base substrate is made of a glass material and a bonding film is formed on the upper surface of the base substrate. The lid substrate is made of a glass material, includes a recess for a cavity, and is bonded to the base substrate with the bonding film interposed therebetween so that the recess faces the base substrate. The piezoelectric vibrating reed is bonded to the upper surface of the base substrate so as to be received in a cavity that is formed between the base substrate and the lid substrate by the recess. The pair of external electrodes is formed on the lower surface of the base substrate. The pair of through electrodes is formed so as to pass through the base substrate, maintains airtightness in the cavity, and is electrically connected to the pair of external electrodes, respectively. The routing electrodes are formed on the upper surface of the base substrate, and are electrically connected to the piezoelectric vibrating reed bonded to the pair of through electrodes.

### RELATED APPLICATIONS

This application is a continuation of PCT/JP2008/065551 filed on Aug. 29, 2008, which claims priority to Japanese Application No. 2008-036423 filed on Feb. 18, 2008. The entire contents of these applications are incorporated herein by reference.

### TECHNICAL FIELD

The present invention relates to a surface mounted (SMD) piezoelectric vibrator where a piezoelectric vibrating reed is sealed in a cavity formed between two bonded substrates, a method of manufacturing the piezoelectric vibrator, and an oscillator, an electronic device, and a radio clock that each include the piezoelectric vibrator.

### BACKGROUND ART

In recent years, a piezoelectric vibrator, which employs crystals or the like as a time source, as a timing source of a control signal or the like, or as a reference signal source or the like, has been used in cell phones or portable information terminal devices. There are known various types of this kind of piezoelectric vibrator, and one of these is a surface mounted piezoelectric vibrator. As this kind of piezoelectric vibrator, there is generally known a piezoelectric vibrator having a three-layer structure where a piezoelectric substrate including a piezoelectric vibrating reed is bonded to a base substrate and a lid substrate so as to be interposed between the base substrate and the lid substrate in a vertical direction (see Patent Documents 1 and 2).

Here, the piezoelectric vibrator having the three-layer structure will be briefly described. As shown in FIG. 35, a piezoelectric vibrator 200 includes three layers, that is, a piezoelectric substrate 201, a base substrate 202, and a lid substrate 203. The piezoelectric substrate 201 includes a piezoelectric vibrating reed 201a, and the base substrate 202 and the lid substrate 203 are bonded to the piezoelectric substrate 201 so that the piezoelectric substrate is interposed between the base substrate and the lid substrate in a vertical direction.

The piezoelectric substrate 201 is made of a piezoelectric material such as crystal, and includes a frame part 201b and a piezoelectric vibrating reed 201a that is connected to the frame part 201b. Meanwhile, the frame part 201b is bonded to both the substrates 202 and 203.

Meanwhile, the piezoelectric vibrating reed 201a is received in a cavity C that is formed by recesses 202a and 203a formed on both the substrates 202 and 203. Electrodes 204a and 204b, which vibrate the piezoelectric vibrating reed 201a when a voltage is applied to the electrodes, are patterned on the piezoelectric vibrating reed 201a.

Both the substrates 202 and 203 are transparent insulating bodies made of glass or the like, and are bonded (for example, anodically bonded) to the frame part 201b of the piezoelectric substrate 201 with a bonding film 205 interposed between the substrates and the frame part. Further, the recesses 202a and 203a, which form the cavity C, are formed on the inner surfaces of both the substrates 202 and 203 as described above.

External electrodes 206a and 206b are formed on the lower surface of the base substrate 202 of both the substrates 202 and 203 so as to extend to the side surfaces. One external electrode 206a of the external electrodes is electrically connected to one electrode 204a of the piezoelectric vibrating reed 201a, and the other external electrode 206b is electrically connected to the other electrode 204b of the piezoelectric vibrating reed 201a.

Patent Citation 1: JP-A-2006-148758

Patent Citation 2: JP-A-2007-184810

However, the piezoelectric vibrator 200 in the related art still has the following problems.

First, as electronic devices have been reduced in size in recent years, there is a demand for the further reduction in the size of the piezoelectric vibrator 200 that is mounted on various electronic devices. Meanwhile, since the piezoelectric vibrator 200 in the related art has the three-layer structure where the piezoelectric substrate 201 is interposed between the base substrate 202 and the lid substrate 203 in a vertical direction, the piezoelectric vibrator is necessarily thick. For this reason, it was difficult to further reduce the thickness of the piezoelectric vibrator. In particular, since the recesses 202a and 203a for forming the cavity C need to be formed on the base substrate 202 and the lid substrate 203, the thickness of each of the substrates 202 and 203 needs to be set to a thickness that is equal to or larger than a predetermined value. Also with regard to this, it was difficult to reduce the thickness of the piezoelectric vibrator.

The invention has been made in consideration of the above-mentioned circumstances, and an object of the invention is to provide a surface mounted piezoelectric vibrator that is much thinner and more compact than the piezoelectric vibrator in the related art.

Further, there are provided a method of efficiently manufacturing the piezoelectric vibrators at a time, and an oscillator, an electronic device, and a radio clock that each include the piezoelectric vibrator.

### SUMMARY OF THE INVENTION

The invention provides the following means in order to solve the above-mentioned problems.

(1) According to the invention, there is provided a method of manufacturing a plurality of piezoelectric vibrators at a time by using a base substrate wafer and a lid substrate wafer. A piezoelectric vibrating reed of the piezoelectric vibrator is sealed in a cavity formed between a base substrate and a lid substrate that are bonded to each other. The method includes a recess forming process for forming a plurality of recesses for cavities, which form the cavities when both the wafers are superimposed, on the lid substrate wafer; a through hole forming process for forming a plurality of pairs of through holes that pass through the base substrate wafer; a through electrode forming process for forming a plurality of pairs of through electrodes by filling the plurality of pairs of through holes with a conductive material; a bonding film forming process for forming a bonding film on the upper surface of the base substrate wafer so that the bonding film surrounds the recesses; a routing electrode forming process for forming a plurality of routing electrodes, which is each electrically connected to the pairs of through electrodes, on the upper surface of the base substrate wafer; a mounting process for bonding the plurality of piezoelectric vibrating reeds to the upper surface of the base substrate wafer through the routing electrodes; a superimposing process for superimposing the lid substrate wafer on the base substrate wafer so that the piezoelectric vibrating reeds are received in the cavities surrounded by the recesses and both the wafers; a bonding process for bonding the lid substrate wafer to the base substrate wafer with the bonding film interposed therebetween and sealing the piezoelectric vibrating reeds in the cavities; an external electrode forming process forming a plurality of pairs of external electrodes, which is each electrically connected to the pairs of through electrodes, on the lower surface of the base substrate wafer; and a cutting process for cutting both the wafers, which are bonded to each other, into the plurality of piezoelectric vibrators.

According to the method, first, there is performed a recess forming process for forming a plurality of recesses for cavities on the lid substrate wafer. These recesses are recesses that form the cavities when both the wafers are superimposed later. Further, before, after or simultaneously with this process, there is performed a through hole forming process for forming a plurality of pairs of through holes that pass through the base substrate wafer. In this case, when both the wafers are superimposed later, the plurality of pairs of through holes is formed so as to be in the recesses formed on the lid substrate wafer. Subsequently, there is performed a through electrode forming process for forming a plurality of pairs of through electrodes by filling the plurality of pairs of through holes with a conductive material.

Then, there is performed a routing electrode forming process for forming a plurality of routing electrodes, which is each electrically connected to the pairs of through electrodes, on the upper surface of the base substrate wafer by performing patterning on the upper surface of the base substrate wafer with a conductive material. In this case, when both the wafers are superimposed later, the routing electrodes are formed so as to be in the recesses formed on the lid substrate wafer. Further, before, after or simultaneously with the routing electrode forming process, there is performed a bonding film forming process for forming a bonding film on the upper surface of the base substrate wafer so that the bonding film surrounds the recesses.

Further, there is performed a mounting process for bonding the plurality of piezoelectric vibrating reeds to the upper surface of the base substrate wafer through the routing electrodes. Accordingly, the respective bonded piezoelectric vibrating reeds are electrically connected to the pairs of through electrodes through the routing electrodes.

After the mounting is completed, there is performed a superimposing process for superimposing the lid substrate wafer on the base substrate wafer. Accordingly, the plurality of bonded piezoelectric vibrating reeds is received in the cavities that are surrounded by the recesses and both the wafers.

After that, there is performed a bonding process for bonding the lid substrate wafer and the base substrate wafer, which are superimposed, with the bonding film interposed therebetween. Accordingly, it may be possible to seal the piezoelectric vibrating reeds in the cavities. In this case, since the through holes formed at the base substrate wafer are closed by the through electrodes, the airtightness in the cavities is not impaired by the through holes. Further, after the bonding, there is performed an external electrode forming process for forming a plurality of pairs of external electrodes, which is each electrically connected to the pairs of through electrodes, on the lower surface of the base substrate wafer by performing patterning on the lower surface of the base substrate wafer with a conductive material. Due to this process, it may be possible to activate the piezoelectric vibrating reed, which is sealed in the cavity, by using the external electrodes.

Finally, there is performed a cutting process for cutting the base substrate wafer and the lid substrate wafer, which are bonded to each other, into the plurality of piezoelectric vibrators.

As a result, it may be possible to manufacture a plurality of surface mounted piezoelectric vibrators, of which the piezoelectric vibrating reed is sealed in a cavity formed between a base substrate and a lid substrate that are anodically bonded to each other, at a time. In particular, unlike the three-layer structure in the related art, the piezoelectric vibrator has the two-layer structure where the base substrate and the lid substrate are bonded to each other. Accordingly, it may be possible to reduce the entire thickness of the piezoelectric vibrator by as much as the thickness of the piezoelectric substrate in the related art. Therefore, it may be possible to further reduce the thickness of the piezoelectric vibrator in comparison with the related art, and to make the piezoelectric vibrator compact.

(2) In the mounting process, bumps may be formed on the routing electrodes and the piezoelectric vibrating reeds may then be bonded to the upper surface of the base substrate wafer through the bumps.

In this case, since being bonded to the upper surface of the base substrate by the bumps, the piezoelectric vibrating reed is supported so as to be floating away from the base substrate. Accordingly, it may be possible to naturally secure a minimum vibration gap that is required for vibration. Therefore, unlike in the lid substrate, the recesses for the cavities do not need to be formed on the base substrate and the base substrate may be formed of a flat plate-shaped substrate. For this reason, it may be possible to reduce the thickness of the base substrate by as much as the recesses are not considered. Even in this regard, it may be possible to reduce the thickness of the piezoelectric vibrator.

(3) In the mounting process, the bumps may be formed after a plasma cleaning treatment is performed on the pairs of routing electrodes for at least 10 seconds.

In this case, before the bumps are formed, a plasma cleaning treatment is performed by applying plasma (for example, oxygen plasma) to the routing electrodes. Accordingly, it may be possible to remove sources of pollution, such as dust, to clean the surface on which the bumps are to be formed, and to modify the surface. In particular, since plasma is applied for at least 10 seconds, it may be possible to reliably remove sources of pollution. Accordingly, it may be possible to improve a contact property and an adhesive property between the routing electrode and the bump, and to increase the resistance of the bumps to shear peeling.

For this reason, it may be possible to improve the mounting performance of the piezoelectric vibrating reed. As a result, it may be possible to improve the quality of the piezoelectric vibrator.

(4) After the through hole forming process, there may be performed a surface machining process for machining the upper surface of the base substrate wafer so that an arithmetic mean roughness Ra is 10 nm or less.

In this case, before the bumps are formed, the arithmetic mean roughness Ra of the upper surface of the base substrate wafer is set to 10 nm or less. Accordingly, it may be possible to make the upper surface of the base substrate wafer, which is a base on which the bumps are formed, to be as close as possible to a flat and smooth surface. For this reason, it may also be possible to improve a contact property and an adhesive property between the routing electrode and the bump, and to increase the resistance of the bumps to shear peeling. Accordingly, it may be possible to improve the mounting performance of the piezoelectric vibrating reed and to improve the quality of the piezoelectric vibrator.

(5) In the bonding process, the base substrate wafer and the lid substrate wafer may be anodically bonded to each other.

In this case, since the base substrate wafer and the lid substrate wafer are anodically bonded to each other, it may be possible to fix both the wafers while both the wafers further come into close contact with each other. Accordingly, it may be possible to more reliably seal the piezoelectric vibrating reed in the cavity and to improve vibration characteristics.

(6) The recess forming process may include a printing process for screen printing paste in a predetermined pattern on the surface of the lid substrate wafer, a drying process for drying the printed paste, and a firing process for firing the applied and dried paste after repeatedly performing the printing process and the drying process several times until the recesses are formed by the application of the paste.

In this case, it may be possible to form the recesses without cutting such as etching when the recesses for cavities are formed on the lid substrate wafer. First, there is performed a printing process for screen printing the paste in a predetermined pattern, that is, so as to surround portions, which form the recesses, on the surface of the lid substrate wafer. Subsequently, there is performed a drying process for drying the printed paste. Further, new paste is screen printed and applied on the dried paste by performing the printing process again. As described above, the printing process and the drying process are repeatedly performed several times until the recesses are formed by the application of the paste. After the recesses are formed by the application of the paste, there is performed a firing process for hardening the paste by firing the applied and dried paste.

As a result, it may be possible to form the recesses on the lid substrate wafer without cutting such as etching. In particular, since it is not necessary to cut the lid substrate wafer, it may be possible to reduce the load to be applied to the wafer and to achieve an improvement in the quality of the piezoelectric vibrator.

(7) The through hole forming process may include a setting process for setting the base substrate wafer between a lower die and an upper die that including pins that protrude toward the lower die, a pressing process for pressing the base substrate wafer by the lower and upper dies when the base substrate wafer is heated up to a predetermined temperature and forming the through holes by the pins, and a cooling process for cooling and solidifying the base substrate wafer.

In this case, when the through holes are formed on the base substrate wafer, it may be possible to reliably form the through holes by a simple method using a die.

First, there is performed a setting process for setting the base substrate wafer between a lower die and an upper die. Further, there is performed a pressing process for pressing the base substrate wafer by the lower and upper dies when the base substrate wafer is heated up to a predetermined temperature and forming the through holes at the base substrate wafer by the pins of the upper die. Furthermore, finally, there is performed a cooling process for cooling and solidifying the base substrate wafer. Accordingly, it may be possible to reliably form the through holes at a time. In particular, since the die including the lower and upper dies are used, it may be possible to improve the accuracy of the positions of the through holes.

(8) A wafer, which has a circular shape in plane view, may be used as the base substrate wafer.

In this case, since the base substrate wafer has a circular shape, the base substrate wafer is hardly deformed even though expansion and contraction occur due to the heating due to the pressing process and the cooling due to the cooling process. Accordingly, it may be possible to maintain a high level of accuracy of dimension and thickness. If a wafer has a rectangular shape in plane view, there is a concern that the wafer is deformed when the wafer expands and contracts due to heating and cooling. For this reason, the accuracy of dimension and thickness is lowered. Since the wafer has corners, internal stress is apt to be concentrated near the corners during the expansion. For this reason, an expansion state and a contraction state become non-uniform. Accordingly, it is considered that the wafer is difficult to return to its original state. Further, if a wafer having a rectangular shape in plane view is used, the accuracy of dimension and thickness is lowered and an expansion state and a contraction state become non-uniform, so that excessive loads are applied to the pins of the upper die. For this reason, there has been a possibility that the pins are deformed or bent.

However, since a circular wafer without corners is used, there is less concern that the above-mentioned problems are generated even though through holes are formed by a press work accompanying with heating and cooling.

(9) Further, according to the invention, there is provided a piezoelectric vibrator. The piezoelectric vibrator includes a base substrate, a lid substrate, a piezoelectric vibrating reed, a pair of external electrodes, a pair of through electrodes, and routing electrodes. The base substrate is made of a glass material, and a bonding film is formed on the upper surface of the base substrate. The lid substrate is made of a glass material, includes a recess for a cavity, and is bonded to the base substrate with the bonding film interposed therebetween so that the recess faces the base substrate. The piezoelectric vibrating reed is bonded to the upper surface of the base substrate so as to be received in a cavity that is formed between the base substrate and the lid substrate by the recess. The pair of external electrodes is formed on the lower surface of the base substrate. The pair of through electrodes is each formed so as to pass through the base substrate, maintains airtightness in the cavity, and is electrically connected to the pair of external electrodes. The routing electrodes are formed on the upper surface of the base substrate and are electrically connected to the piezoelectric vibrating reed bonded to the pair of through electrodes.

In this case, it may be possible to achieve the same advantages as the advantages of the method of manufacturing the piezoelectric vibrators according to (1).

(10) The piezoelectric vibrating reed may be bonded to the upper surface of the base substrate through bumps.

In this case, it may be possible to achieve the same advantages as the advantages of the method of manufacturing the piezoelectric vibrators according to (2).

(11) The bumps may be formed on an area on which a plasma cleaning treatment has been performed for at least 10 seconds.

In this case, it may be possible to achieve the same advantages as the advantages of the method of manufacturing the piezoelectric vibrators according to (3).

(12) The arithmetic mean roughness Ra of the upper surface of the base substrate may be 10 nm or less.

In this case, it may be possible to achieve the same advantages as the advantages of the method of manufacturing the piezoelectric vibrators according to (4).

(13) The base substrate and the lid substrate may be anodically bonded to each other.

In this case, it may be possible to achieve the same advantages as the advantages of the method of manufacturing the piezoelectric vibrators according to (5).

(14) Furthermore, according to the invention, there is provided an oscillator where the piezoelectric vibrator according to any one of (9) to (13) is electrically connected to an integrated circuit as an oscillating component.

(15) Further, according to the invention, there is provided an electronic device where the piezoelectric vibrator according to any one of (9) to (13) is electrically connected to a clock unit.

(16) Furthermore, according to the invention, there is provided a radio clock where the piezoelectric vibrator according to any one of (9) to (13) is electrically connected to a filter unit.

Since the oscillator, the electronic device, and the radio clock each include the piezoelectric vibrator that is thinner and more compact than a piezoelectric vibrator in the related art, it may also be possible to make the oscillator, the electronic device, and the radio clock to be compact and to meet a demand for the further reduction in size.

### ADVANTAGEOUS EFFECTS

The piezoelectric vibrator according to the invention can be formed to be thinner and more compact than a piezoelectric vibrator in the related art.

Further, according to the method of manufacturing the piezoelectric vibrators of the invention, it may be possible to efficiently manufacture the surface mounted piezoelectric vibrators, which are made compact, at a time. Accordingly, it may be possible to reduce the manufacturing cost of the piezoelectric vibrators.

Furthermore, since the oscillator, the electronic device, and the radio clock each include the piezoelectric vibrator, likewise, it may also be possible to make the oscillator, the electronic device, and the radio clock to be compact and to meet a demand for the further reduction in size.

### BRIEF DESCRIPTION OF THE DRAWINGS

FIG. 1 is a view showing an embodiment of the invention, and is a perspective view showing the appearance of a piezoelectric vibrator.

FIG. 2 is a view showing the internal structure of the piezoelectric vibrator shown in FIG. 1, and is a view showing a piezoelectric vibrating reed from the upper side when a lid substrate is removed.

FIG. 3 is a cross-sectional view of the piezoelectric vibrator taken along a line A-A shown in FIG. 2.

FIG. 4 is an exploded perspective view of the piezoelectric vibrator shown in FIG. 1.

FIG. 5 is a top view of a piezoelectric vibrating reed of the piezoelectric vibrator shown in FIG. 1.

FIG. 6 is a bottom view of the piezoelectric vibrating reed shown in FIG. 5.

FIG. 7 is a cross-sectional view taken along a line B-B shown in FIG. 5.

FIG. 8 is a flowchart illustrating a process flow during the manufacture of the piezoelectric vibrator shown in FIG. 1.

FIG. 9 is a view illustrating one process when a piezoelectric vibrator is manufactured according to the flowchart illustrated in FIG. 8, and is a view showing that a plurality of recesses is formed on a lid substrate wafer that is a material of a lid substrate.

FIG. 10 is a view illustrating one process when a piezoelectric vibrator is manufactured according to the flowchart illustrated in FIG. 8, and is a view showing a state where pairs of through holes are formed on a base substrate wafer that is a material of a base substrate.

FIG. 11 is a view showing a state where a bonding film and routing electrodes are patterned on the upper surface of the base substrate wafer and through electrodes are formed in the pairs of through holes after the state shown in FIG. 10.

FIG. 12 is a view showing the entire base substrate wafer that is in the state shown in FIG. 11.

FIG. 13 is a view illustrating one process when a piezoelectric vibrator is manufactured according to the flowchart illustrated in FIG. 8, and is an exploded perspective view of a wafer where the base substrate wafer and the lid substrate wafer are anodically bonded to each other so that the piezoelectric vibrating reeds are in cavities.

FIG. 14 is an equivalent circuit diagram of the piezoelectric vibrator.

FIG. 15 is a view showing an expression for calculating series capacitance that is shown in FIG. 14.

FIG. 16 shows comparison results of C1 and C0 between when the piezoelectric vibrating reed is mounted by soldering and when the piezoelectric vibrating reed is mounted by bump bonding.

FIG. 17 is a view showing a CL curve.

FIG. 18 is a view showing an embodiment according to the invention, and is a view showing the configuration of an oscillator.

FIG. 19 is a view showing an embodiment according to the invention, and is a view showing the configuration of an electronic device.

FIG. 20 is a view showing an embodiment according to the invention, and is a view showing the configuration of a radio clock.

FIG. 21 is a view illustrating a modification when a piezoelectric vibrator according to the invention is manufactured, and is a flowchart when recesses for cavities are formed by the screen printing of paste.

FIG. 22 is a view illustrating one process when recesses are formed according to the flowchart illustrated in FIG. 21, and is a view showing a state where a printing mask is set after a lid substrate wafer is fixed on a wafer fixing plate.

FIG. 23 is a view showing a state where the screen printing of paste is being performed from the state shown in FIG. 22.

FIG. 24 is a view showing a state where recesses are formed by repeatedly performing screen printing and drying from the state shown in FIG. 23.

FIG. 25 is a cross-sectional view taken along a line C-C shown in FIG. 24.

FIG. 26 is a view illustrating a modification when a piezoelectric vibrator according to the invention is manufactured, and is a flowchart when through holes are formed at a base substrate wafer by pressing a die.

FIG. 27 is a view illustrating one process when through holes are formed according to the flowchart illustrated in FIG. 26, and is a view showing a state where a base substrate wafer is set between lower and upper dies.

FIG. 28 is a view showing a state where the base substrate wafer is pressed by the lower and upper dies after the state shown in FIG. 27.

FIG. 29 is a view showing the comparison results of a scratch test of bumps between when bumps are formed without a plasma cleaning treatment and when bumps are formed after a plasma cleaning process, in regard to the manufacture of the piezoelectric vibrator according to the invention.

FIG. 30 is an enlarged view of paste containing metal fine particles.

FIG. 31 is a view showing a modification of a piezoelectric vibrator according to the invention, and is a view showing a piezoelectric vibrator where through electrodes are formed using the paste shown in FIG. 30.

FIG. 32 is a view showing another modification of a piezoelectric vibrator according to the invention, and is a view showing a piezoelectric vibrator where glass beads are contained in the paste shown in FIG. 30 and through electrodes are formed using the paste.

FIG. 33 is a view showing still another modification of a piezoelectric vibrator according to the invention, and is a view showing a piezoelectric vibrator where through electrodes are formed by the firing of a glass cylindrical body and a conductive core member.

FIG. 34 is a perspective view of the cylindrical body shown in FIG. 33.

FIG. 35 is a cross-sectional view of an example of a piezoelectric vibrator having the three-layer structure in the related art.

### DETAILED DESCRIPTION OF THE PREFERRED EMBODIMENTS

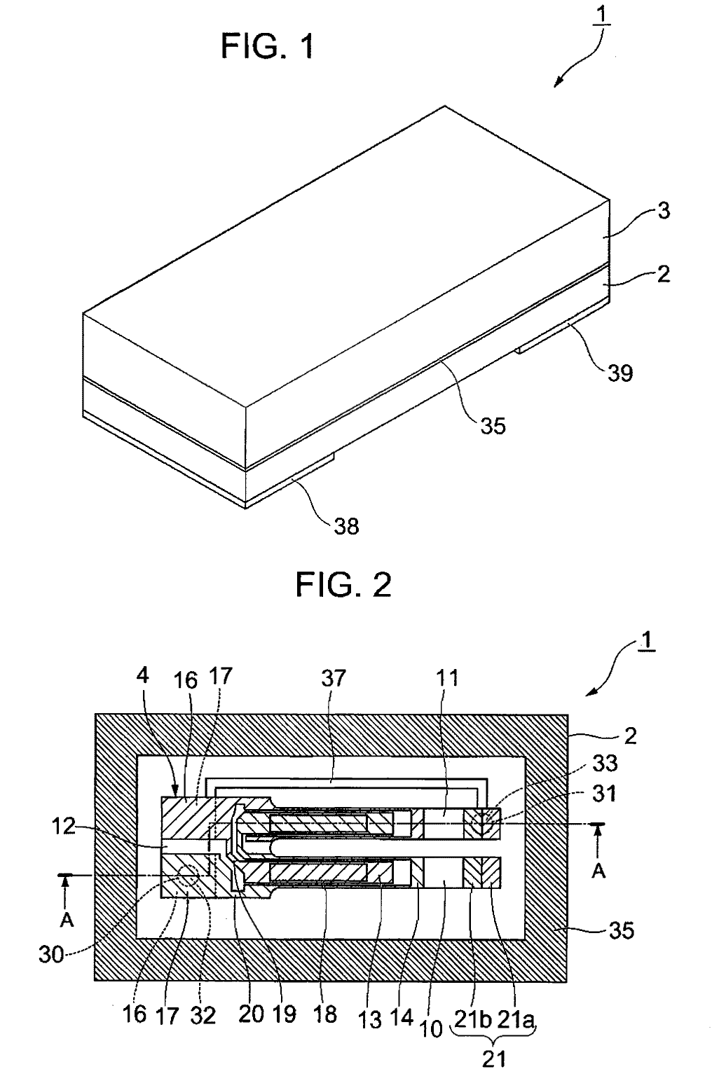

An embodiment of the invention will be described below with reference to FIGS. 1 to 17.

As shown in FIGS. 1 to 4, a piezoelectric vibrator 1 according to this embodiment is formed in a box shape where two layers (a base substrate 2 and a lid substrate 3) are laminated, and is a surface mounted piezoelectric vibrator where a piezoelectric vibrating reed 4 is received in an inner cavity C.

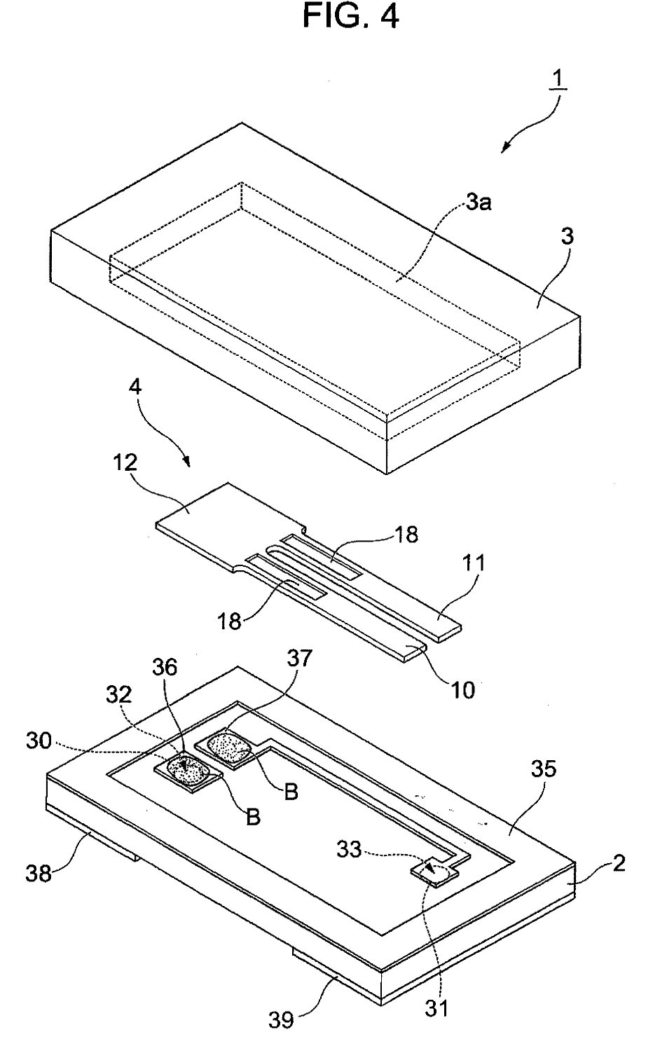

Meanwhile, for the easy understanding of drawings, an excitation electrode 15, extraction electrodes 19 and 20, mount electrodes 16 and 17, and a weight metal film 21, which are to be described below, are not shown in FIG. 4.

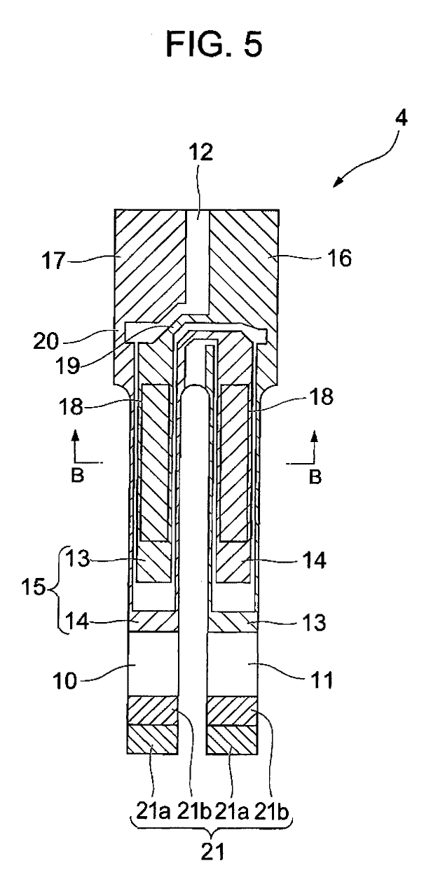

As shown in FIGS. 5 to 7, the piezoelectric vibrating reed 4 is a tuning-fork type vibrating reed that is made of a piezoelectric material, such as crystals, lithium tantalite, or lithium niobate. When a predetermined voltage is applied to the piezoelectric vibrating reed, the piezoelectric vibrating reed vibrates.

The piezoelectric vibrating reed 4 includes a pair of vibration arm portions 10 and 11 that is disposed parallel to each other, a base portion 12 that integrally fixes the base ends of the pair of vibration arm portions 10 and 11, excitation electrodes 15 that each include first and second excitation electrodes 13 and 14, and mount electrodes 16 and 17 that are electrically connected to the first and second excitation electrodes 13 and 14. The first and second excitation electrodes are formed on the outer surfaces of the pair of vibration arm portions 10 and 11, and vibrate the pair of vibration arm portions 10 and 11.

Further, the piezoelectric vibrating reed 4 of this embodiment includes groove portions 18 that are formed on the main surfaces of the pair of vibration arm portions 10 and 11 in the longitudinal directions of the vibration arm portions 10 and 11, respectively. The groove portions 18 are formed from the base ends of the vibration arm portions 10 and 11 to the substantially middle portions thereof.

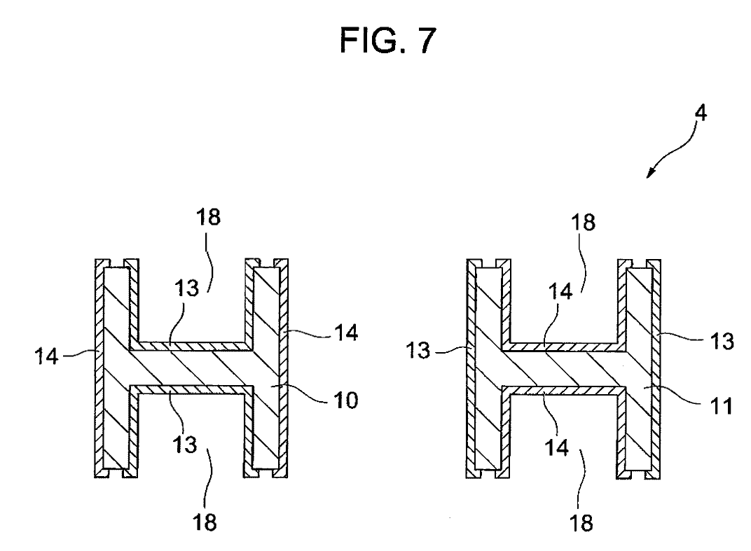

The excitation electrode 15 including the first and second excitation electrodes 13 and 14 is an electrode for vibrating the pair of vibration arm portions 10 and 11 at a predetermined resonant frequency in a direction where the vibration arm portions approach each other or are separated from each other. The first and second excitation electrodes are patterned on the outer surfaces of the pair of vibration arm portions 10 and 11 so as to be electrically isolated, respectively. Specifically, as shown in FIG. 7, the first excitation electrode 13 is mainly formed on the groove portions 18 of one vibration arm portion 10 and both side surfaces of the other vibration arm portion 11, and the second excitation electrode 14 is mainly formed on both side surfaces of one vibration arm portion 10 and the groove portions 18 of the other vibration arm portion 11.

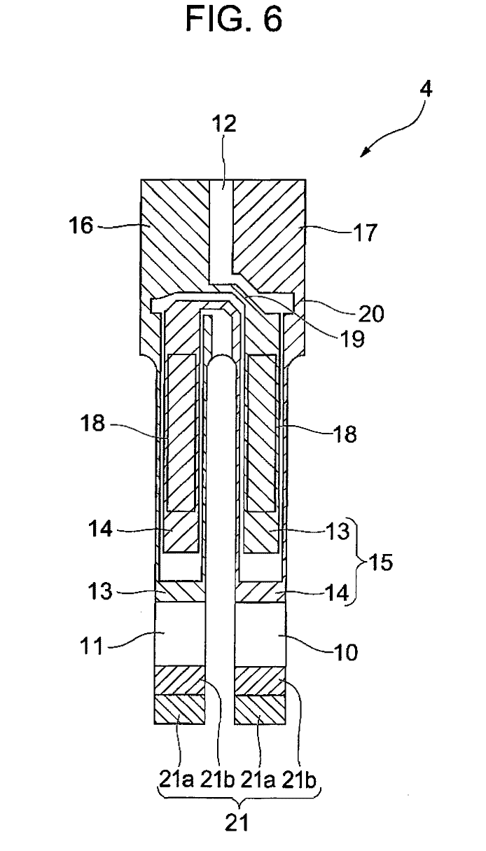

As shown in FIGS. 5 and 6, the first and second excitation electrodes 13 and 14 are electrically connected to the mount electrodes 16 and 17 through the extraction electrodes 19 and 20 on both the main surfaces of the base portion 12, respectively. Further, a voltage is applied to the piezoelectric vibrating reed 4 through the mount electrodes 16 and 17.

Meanwhile, the excitation electrodes 15, the mount electrodes 16 and 17, and the extraction electrodes 19 and 20, which have been described above, are formed by forming conductive films made of, for example, chrome (Cr), nickel (Ni), aluminum (Al), or titanium (Ti).

A weight metal film 21, which performs adjustments (frequency adjustment) so as to make the vibrational states of the vibration arm portions be within a predetermined frequency range, is formed at the ends of the pair of vibration arm portions 10 and 11. Meanwhile, the weight metal film 21 is divided into a rough adjustment film 21a that is used to roughly adjust frequency and a fine adjustment film 21b that is used to finely adjust frequency. It may be possible to make the frequency of the pair of vibration arm portions 10 and 11 be within the nominal frequency range of a device by performing frequency adjustment with the rough and fine adjustment films 21a and 21b.

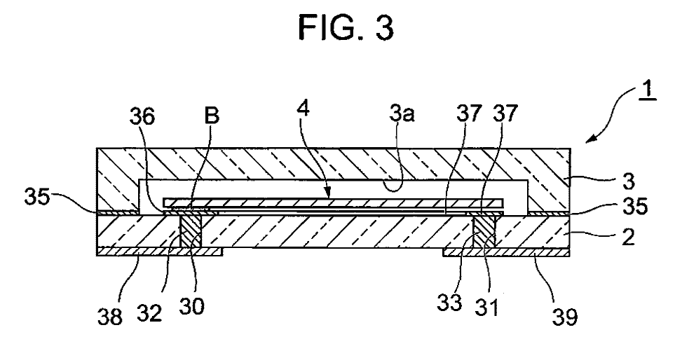

As shown in FIGS. 3 and 4, the piezoelectric vibrating reed 4 having the above-mentioned structure is bonded by bumps B, which are made of gold or the like, on the upper surface of the base substrate 2. More specifically, the pair of mount electrodes 16 and 17 are bonded to the two bumps B, which are formed on routing electrodes 36 and 37 (to be described below) patterned on the upper surface of the base substrate 2, so as to each come into contact with the bumps. Accordingly, the piezoelectric vibrating reed 4 is supported so as to be floating away from the upper surface of the base substrate 2, and the mount electrodes 16 and 17 are electrically connected to the routing electrodes 36 and 37.

The lid substrate 3 is a transparent insulating substrate that is made of a glass material, for example, soda-lime glass. The lid substrate is formed in the shape of a plate as shown in FIGS. 1, 3, and 4. Further, a rectangular recess 3a, in which the piezoelectric vibrating reed 4 is received, is formed on a bonding surface of the lid substrate to which the base substrate 2 is bonded. The recess 3a is a recess 3a that forms a cavity C receiving the piezoelectric vibrating reed 4 when both the substrates 2 and 3 are superimposed. Further, the lid substrate 3 is anodically bonded to the base substrate 2 so that the recess 3a faces the base substrate 2.

Like the lid substrate 3, the base substrate 2 is a transparent insulating substrate that is made of a glass material, for example, soda-lime glass. As shown in FIGS. 1 to 4, the base substrate is formed in the shape of a plate so as to have a size capable of being superimposed on the lid substrate 3.

A pair of through holes 30 and 31 passing through the base substrate 2 is formed at the base substrate 2. In this case, the pair of through holes 30 and 31 is formed so as to be in the cavity C. In more detail, one through hole 30 is positioned so as to correspond to the base portion 12 of the mounted piezoelectric vibrating reed 4, and the other through hole 31 is positioned so as to correspond to the ends of the vibration arm portions 10 and 11. Further, the through holes 30 and 31 that pass straight through the base substrate 2 have been exemplified in this embodiment, but the invention is not limited thereto. For example, a tapered through hole of which the diameter is gradually reduced toward the lower surface of the base substrate 2 may be formed. In any case, the through holes only need to pass through the base substrate 2.

Further, a pair of through electrodes 32 and 33, which is formed so as to fill the through holes 30 and 31, is formed at the pair of through holes 30 and 31. The through electrodes 32 and 33 function to completely close the through holes 30 and 31 so as to maintain the airtightness in the cavity C and to electrically connect the routing electrodes 36 and 37 to external electrodes 38 and 39 to be described below.

A bonding film 35 for anodic bonding and the pair of routing electrodes 36 and 37 are patterned on the upper surface of the base substrate 2 (the bonding surface to which the lid substrate 3 is bonded) with a conductive material (for example, aluminum). Out of these, the bonding film 35 is formed along the periphery of the base substrate 2 so as to surround the recess 3a that is formed on the lid substrate 3.

The pair of routing electrodes 36 and 37 is patterned so as to electrically connect one through electrode 32 of the pair of through electrodes 32 and 33 to one mount electrode 16 of the piezoelectric vibrating reed 4 and electrically connect the other through electrode 33 of the pair of through electrodes to the other mount electrode 17 of the piezoelectric vibrating reed 4. In more detail, as shown in FIGS. 2 and 4, one routing electrode 36 is formed immediately above the through electrode 32 so as to be positioned immediately below the base portion 12 of the piezoelectric vibrating reed 4. Further, the other routing electrode 37 is formed so as to be routed from a position adjacent to one routing electrode 36 to the ends of the vibration arm portions 10 and 11 along the vibration arm portions 10 and 11 and be then positioned immediately above the through electrode 33.

Further, the bumps B are formed on the pair of routing electrodes 36 and 37, and the piezoelectric vibrating reed 4 is mounted using the bumps B. Accordingly, one mount electrode 16 of the piezoelectric vibrating reed 4 is electrically connected to one through electrode 32 through one routing electrode 36, and the other mount electrode 17 is electrically connected to the other through electrode 33 through the other routing electrode 37.

As shown in FIGS. 1, 3, and 4, a pair of external electrodes 38 and 39, which is electrically connected to the pair of through electrodes 32 and 33, respectively, is formed on the lower surface of the base substrate 2. That is, one external electrode 38 is electrically connected to the first excitation electrode 13 of the piezoelectric vibrating reed 4 through the one through electrode 32 and one routing electrode 36. Further, the other external electrode 39 is electrically connected to the second excitation electrode 14 of the piezoelectric vibrating reed 4 through the other through electrode 33 and the other routing electrode 37.

A predetermined driving voltage is applied to the external electrodes 38 and 39 formed on the base substrate 2 for the operation of the piezoelectric vibrator 1 having the above-mentioned structure. Accordingly, it may be possible to make current flow in the excitation electrode 15 including the first and second excitation electrodes 13 and 14 of the piezoelectric vibrating reed 4, and to vibrate the pair of vibration arm portions 10 and 11 at a predetermined frequency in a direction where the vibration arm portions approach each other or are separated from each other. Further, the vibration of the pair of vibration arm portions 10 and 11 may be used as a time source, as a timing source of a control signal, as a reference signal source, and the like.

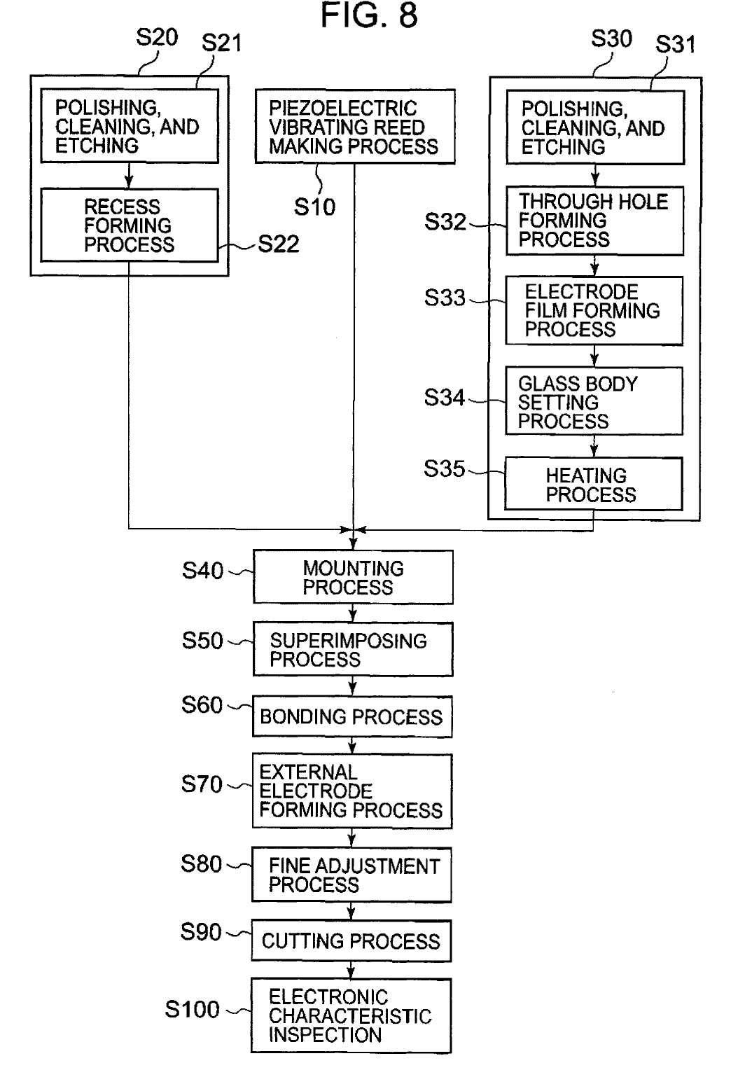

A method of manufacturing a plurality of the above-mentioned piezoelectric vibrators 1 at a time by using a base substrate wafer 40 and a lid substrate wafer 50, which have a circular shape in plan view, will be described below with reference to the flowchart shown in FIG. 8.

First, the piezoelectric vibrating reeds 4 shown in FIGS. 5 to 7 are formed by a piezoelectric vibrating reed making process (S10). Specifically, first, a Lambert raw stone of crystals is sliced at a predetermined angle so that wafers having a uniform thickness are formed. Subsequently, after the wafer is roughly worked by lapping, a work-affected layer is removed by etching. After that, mirror polishing working such as polishing is performed so that a wafer having a predetermined thickness is formed. Subsequently, after an appropriate treatment such as cleaning is performed on the wafer, the wafer is patterned so as to have the outline of the piezoelectric vibrating reed 4 by a photolithographic technique and the excitation electrodes 15, the extraction electrodes 19 and 20, the mount electrodes 16 and 17, and the weight metal films 21 are formed by patterning and forming of a metal film. Accordingly, it may be possible to form a plurality of piezoelectric vibrating reeds 4.

After the piezoelectric vibrating reeds 4 are made, the rough adjustment of a resonant frequency is performed. The rough adjustment of the resonant frequency is performed by irradiating the rough adjustment film 21a of the weight metal film 21 with laser light so that a part of the rough adjustment film is evaporated and the weight of the weight metal film is thus changed. Meanwhile, the fine adjustment for more accurately adjusting the resonant frequency is performed after mounting. This will be described below.

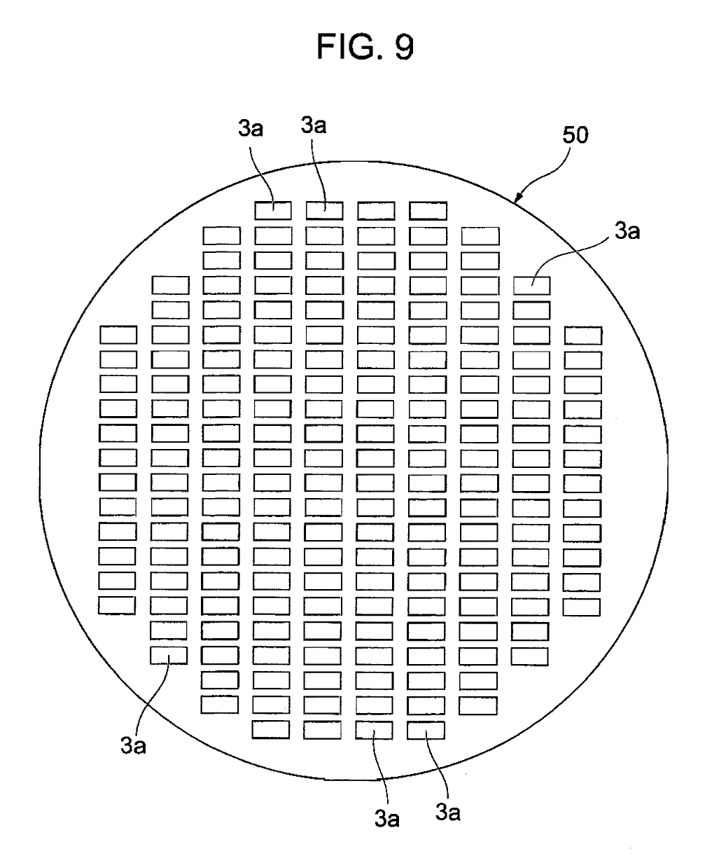

After that, there is performed a first wafer making process (S20) for making the lid substrate wafer 50, which later forms the lid substrate 3, up to a state immediately before the anodic bonding is performed. First, after soda-lime glass is polished up to a predetermined thickness and cleaned, a disk-shaped lid substrate wafer 50, of which the outermost work-affected layer is removed by etching or the like, is formed as shown in FIG. 9 (S21). Then, there is performed a recess forming process (S22) for forming a plurality of recesses 3a for cavities C on the bonding surface of the lid substrate wafer 50 in row and column directions by etching or the like. The first wafer making process is completed at this point in time.

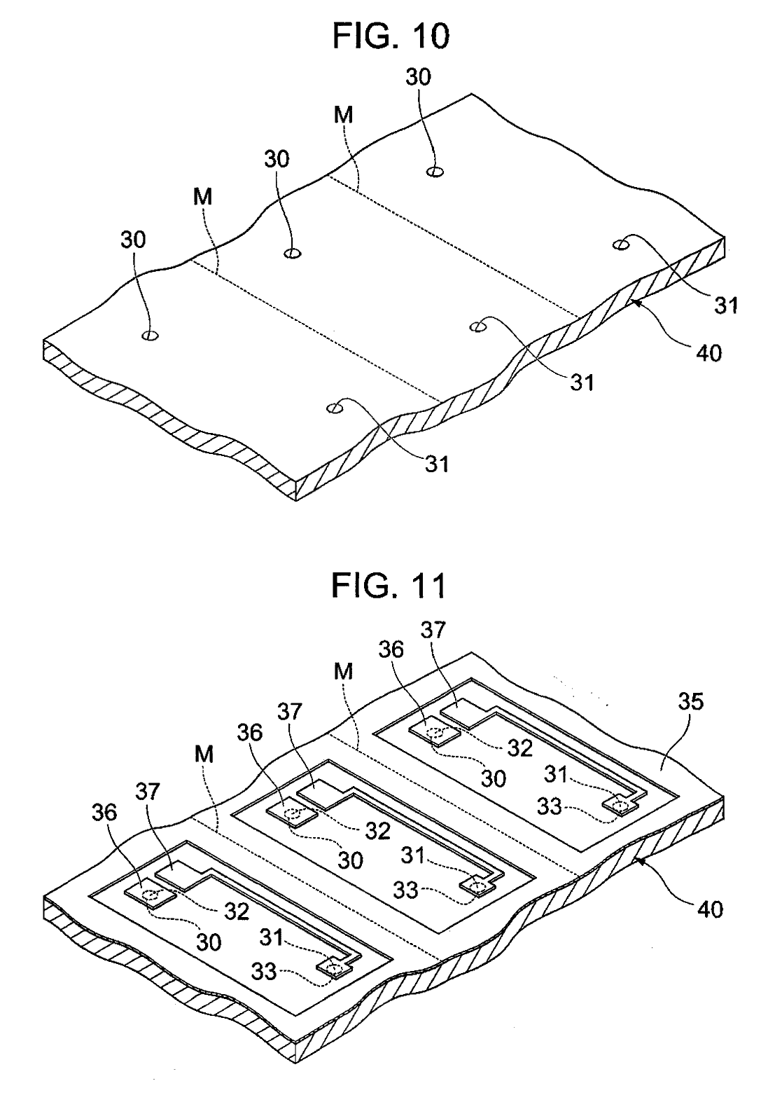

Subsequently, before, after or simultaneously with the process, there is performed a second wafer making process (S30) for making the base substrate wafer 40, which later forms the base substrate 2, up to a state immediately before the anodic bonding is performed. First, after soda-lime glass is polished up to a predetermined thickness and cleaned, a disk-shaped base substrate wafer 40 of which the outermost work-affected layer is removed by etching or the like is formed (S31). Then, there is performed a through hole forming process (S32) for forming a plurality of pairs of through holes 30 and 31 passing through the base substrate wafer 40 as shown in FIG. 10. Meanwhile, dotted lines M shown in FIG. 10 are cutting lines along which cutting is performed in a cutting process to be performed later.

In this case, the plurality of pairs of through holes 30 and 31 is formed so as to be in the recesses 3a formed on the lid substrate wafer 50 when both the wafers 40 and 50 are superimposed later. In addition, one through hole 30 is positioned so as to correspond to the base portion 12 of the piezoelectric vibrating reed 4 to be mounted later, and the other through hole 31 is positioned so as to correspond to the ends of the vibration arm portions 10 and 11.

Subsequently, there is performed a through electrode forming process (S33) for forming pairs of through electrodes 32 and 33 by filling the plurality of pairs of through holes 30 and 31 with a conductive material (not shown).

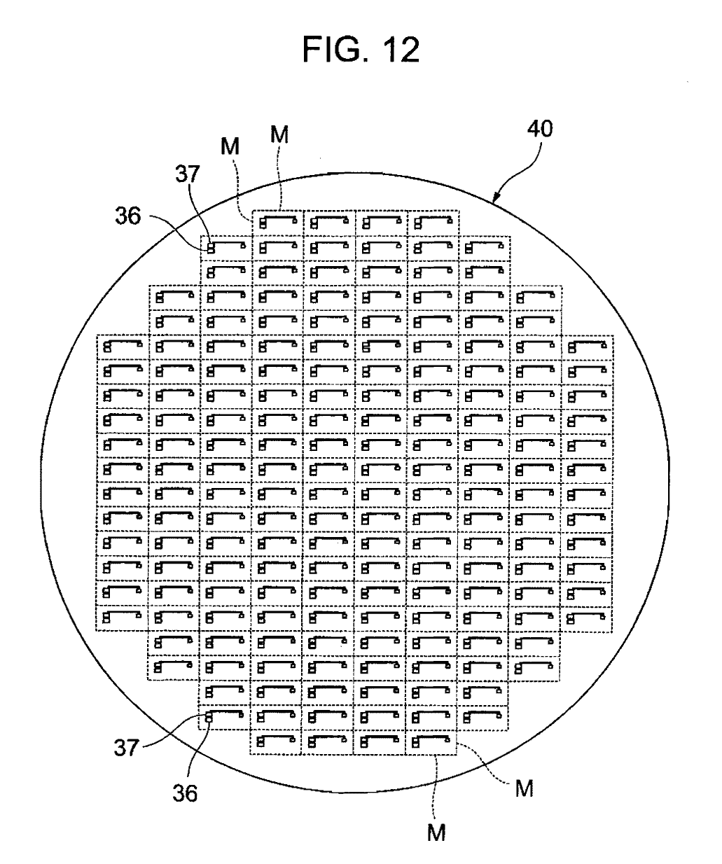

Subsequently, there is performed a bonding film forming process (S34) for forming the bonding film 35 as shown in FIGS. 11 and 12 by performing patterning on the upper surface of the base substrate wafer 40 with a conductive material, and there is performed a routing electrode forming process (S35) for forming a plurality of routing electrodes 36 and 37, which is electrically connected to the pairs of through electrodes 32 and 33, respectively. Meanwhile, dotted lines M shown in FIGS. 11 and 12 are cutting lines along which cutting is performed in a cutting process to be performed later. Further, the bonding film 35 is not shown in FIG. 12.

One through electrode 32 and one routing electrode 36 are electrically connected to each other and the other through electrode 33 and the other routing electrode 37 are electrically connected to each other by performing this process. The second wafer making process is completed at this point in time.

Meanwhile, in a process sequence shown in FIG. 8, the routing electrode forming process (S35) has been performed after the bonding film forming process (S34). However, the bonding film forming process (S34) may be performed after the routing electrode forming process (S35) in reverse to this process sequence, or both processes may be performed at the same time. In any process sequence, it may be possible to achieve the same advantage. Accordingly, the process sequence may be appropriately changed as needed.

After that, there is performed a mounting process (S40) for bonding, by using the bumps, the plurality of made piezoelectric vibrating reeds 4 to the upper surface of the base substrate wafer 40 through the routing electrodes 36 and 37, respectively. First, the bumps B made of gold or the like are formed on the pairs of routing electrodes 36 and 37. Further, after the base portions 12 of the piezoelectric vibrating reeds 4 are placed on the bumps B, the piezoelectric vibrating reeds 4 are pressed against the bumps B while the bumps B are heated to a predetermined temperature. Accordingly, the piezoelectric vibrating reeds 4 are mechanically supported by the bumps B and the mount electrodes 16 and 17 are electrically connected to the routing electrodes 36 and 37. Therefore, the pair of the excitation electrodes 15 of the piezoelectric vibrating reed 4 is electrically connected to the pair of through electrodes 32 and 33, respectively. In particular, since being bonded by using the bumps, the piezoelectric vibrating reed 4 is supported so as to be floating away from the upper surface of the base substrate wafer 40.

After the mounting of the piezoelectric vibrating reeds 4 is completed, there is performed a superimposing process (S50) for superimposing the lid substrate wafer 50 on the base substrate wafer 40. Specifically, while reference marks (not shown) are used as indexes, both the wafers 40 and 50 are aligned in position. Accordingly, the mounted piezoelectric vibrating reeds 4 are received in the cavities C that are surrounded by the wafers 40 and 50 and the recesses 3a formed on the base substrate wafer 40, respectively.

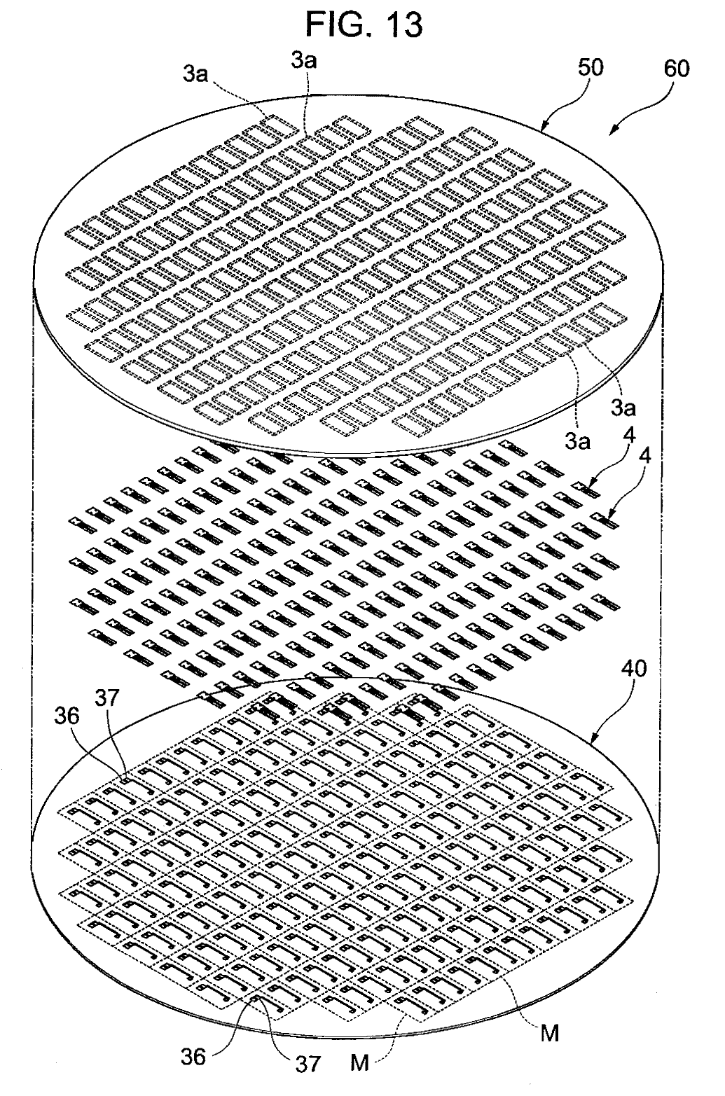

After the superimposing process, there is performed a bonding process (S60) for anodically bonding the two superimposed wafers by applying a predetermined voltage in a predetermined temperature atmosphere after putting two superimposed wafers 40 and 50 in an anodic bonding apparatus (not shown). Specifically, a predetermined voltage is applied between the bonding film 35 and the lid substrate wafer 50. Accordingly, an electrochemical reaction occurs on the interface between the bonding film 35 and the lid substrate wafer 50, and the bonding film and the lid substrate wafer come into close contact with each other and are anodically bonded to each other. Accordingly, it may be possible to seal the piezoelectric vibrating reed 4 in the cavity C, and to obtain a wafer 60 shown in FIG. 13 where the base substrate wafer 40 and the lid substrate wafer 50 are bonded to each other. Meanwhile, for the easy understanding of the drawing, the exploded wafer 60 is shown in FIG. 13, and the bonding film 35 is not shown from the base substrate wafer 40. Meanwhile, dotted lines M shown in FIG. 13 are cutting lines along which cutting is performed in a cutting process to be performed later.

When the anodic bonding is performed, the through holes 30 and 31 formed at the base substrate wafer 40 are completely closed by the through electrodes 32 and 33. Accordingly, airtightness in the cavity C is not impaired by the through holes 30 and 31.

After the above-mentioned anodic bonding is completed, there is performed an external electrode forming process (S70) for forming the plurality of pairs of external electrodes 38 and 39, which is electrically connected to the pairs of through electrodes 32 and 33, respectively, by performing patterning on the lower surface of the base substrate wafer 40 with a conductive material. Due to this process, it is possible to activate the piezoelectric vibrating reed 4, which is sealed in the cavity C, by using the external electrodes 38 and 39.

After that, there is performed a fine adjustment process (S80) for finely adjusting the frequency of each of the piezoelectric vibrators 1 that are sealed in the cavities C in the state of the wafer 60. In detail, a voltage is applied to the external electrodes 38 and 39, so that the piezoelectric vibrating reeds 4 vibrate. Further, while the frequency is measured, laser light is irradiated from the outside through the lid substrate wafer 50, thereby evaporating the fine adjustment film 21b of the weight metal film 21. Accordingly, the weight of the ends of the pair of vibration arm portions 10 and 11 is changed. As a result, it may be possible to finely adjust the frequency of the each of the piezoelectric vibrating reeds 4 so that the frequency of the piezoelectric vibrating reeds is within a predetermined nominal frequency range.

After the fine adjustment of frequency is completed, there is performed a cutting process (S90) for cutting the bonded wafer 60 into small pieces along the cutting lines M shown in FIG. 13. As a result, it may be possible to manufacture a plurality of surface mounted piezoelectric vibrators 1 of which one is shown in FIG. 1 and the piezoelectric vibrating reed 4 is sealed in the cavity C formed between the base substrate 2 and lid substrate 3 anodically bonded to each other.

Meanwhile, the fine adjustment process (S80) may be performed after the wafer is cut into individual piezoelectric vibrators 1 by the cutting process (S90). However, if the fine adjustment process (S80) is previously performed as described above, fine adjustment can be performed in the state of the wafer 60, so that it may be possible to more efficiently perform the fine adjustment of the plurality of piezoelectric vibrators 1. Accordingly, since it may be possible to improve throughput, this is preferable.

After that, an internal electronic characteristic inspection is performed (S100). That is, the drive level characteristics, the resonance resistance value, the resonant frequency (excitation power dependence of resonance resistance value and resonant frequency) and the like of the piezoelectric vibrating reeds 4 are measured and checked. Further, insulation resistance characteristics and the like are also checked. And finally, the appearances of the piezoelectric vibrators 1 are inspected to check for the last time dimension, quality, and the like. As a result, the manufacture of the piezoelectric vibrators 1 is completed.

In particular, the piezoelectric vibrator 1 according to this embodiment has the two-layer structure where the base substrate 2 and the lid substrate 3 are bonded to each other, unlike the three-layer structure in the related art. Accordingly, it may be possible to reduce the entire thickness of the piezoelectric vibrator by as much as the thickness of the piezoelectric substrate in the related art. Therefore, it may be possible to further reduce the thickness of the piezoelectric vibrator in comparison with the related art, and to make the piezoelectric vibrator compact. In addition, as described above, due to the bump bonding, the piezoelectric vibrating reed 4 is supported so as to be floating away from the base substrate 2. Accordingly, it may be possible to naturally secure a minimum vibration gap that is required for vibration. Therefore, unlike in the lid substrate 3, the recesses 3a for cavities C do not need to be formed on the base substrate 2 and the base substrate may be formed of a flat plate-shaped substrate. For this reason, it may be possible to reduce the thickness of the base substrate 2 by as much as the recesses 3a are not considered. Also with regard to this, it may be possible to reduce the thickness of the piezoelectric vibrator 1.

Further, according to the method of this embodiment, it may be possible to manufacture a plurality of piezoelectric vibrators 1, which are made to be thin, at a time. Therefore, it may be possible to reduce the manufacturing cost of the piezoelectric vibrators.

Furthermore, since the piezoelectric vibrating reed 4 is bonded by the bumps, it may be possible to obtain the following advantages in comparison with general soldering.

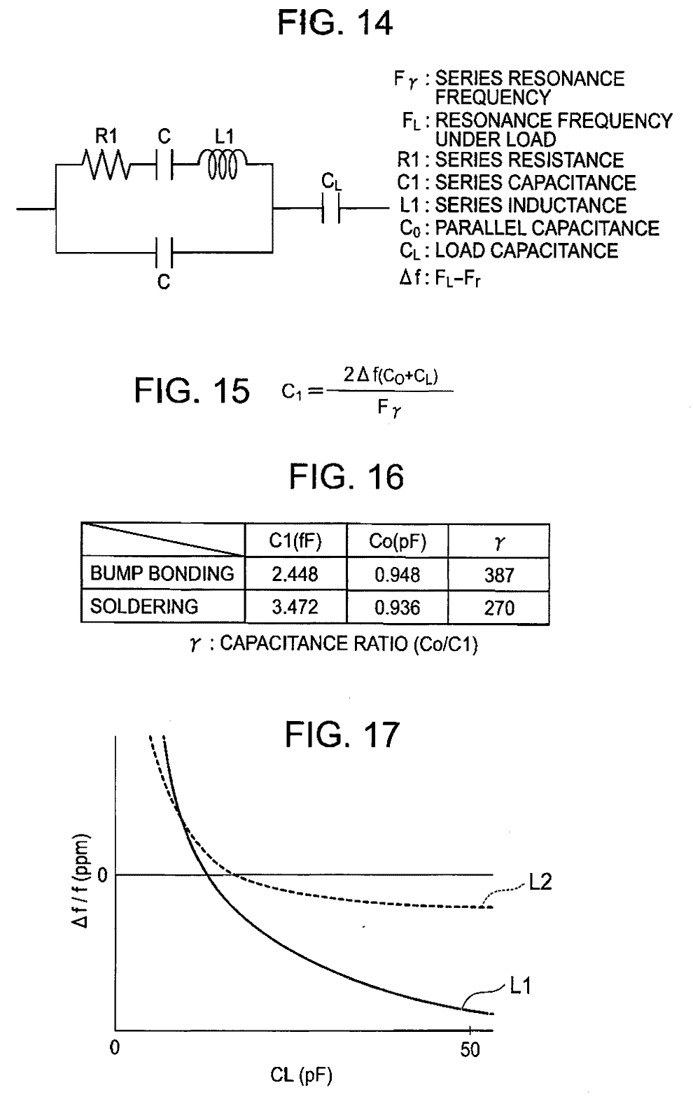

That is, C₀ of the piezoelectric vibrator where the piezoelectric vibrating reed is bonded by the bumps is substantially equal to that of the piezoelectric vibrator where the piezoelectric vibrating reed is bonded by soldering, but it may be possible to make C1 characteristics of the piezoelectric vibrator where the piezoelectric vibrating reed is bonded by the bumps be smaller than that of the piezoelectric vibrator where the piezoelectric vibrating reed is bonded by soldering. C₀ and C1 will be described herein in brief. C₀ is the parallel capacitance of an equivalent circuit of the piezoelectric vibrator that is shown in FIG. 14, and is a value that can be actually measured. Meanwhile, C1 is the series capacitance of the equivalent circuit shown in FIG. 14, and is a value that can be calculated by an expression shown in FIG. 15. Meanwhile, in this case, Δf, C₀, C_{L}, and Fᵣ of the expression are values that can be measured.

Here, FIG. 16 shows the values of actually measured C₀ and calculated C1 of the piezoelectric vibrator where the piezoelectric vibrating reed 4 is mounted by soldering and the piezoelectric vibrator 1 according to the embodiment where the piezoelectric vibrating reed 4 is bonded by the bumps. Meanwhile, both the piezoelectric vibrators have the same structure except that the piezoelectric vibrating reed is bonded by soldering or the bumps.

As a result, as shown in FIG. 16, it was confirmed that C1 of the case of the bump bonding is lower than that of the case of soldering. It is considered that this is caused by the mounting condition of the piezoelectric vibrating reed 4. That is, in the case of soldering, the piezoelectric vibrating reed 4 is mounted on solder so as to come into surface contact with the solder. Meanwhile, in the case of bump bonding, the piezoelectric vibrating reed 4 is mounted on the bumps B in a state which approaches point contact. For this reason, it is considered that C1 is decreased since the piezoelectric vibrating reed floats with less contact.

Further, since C1 is low in the case of bump bonding, it was confirmed that a capacitance ratio γ (C₀/C1) was larger in the case of bump bonding than that in the case of soldering. In general, if the capacitance ratio γ is increased, it may be possible to lower C_{L} (capacitance load) and to achieve low power consumption. Accordingly, if the piezoelectric vibrating reed is bonded by using the bumps, it may be possible to achieve an advantage of manufacturing a piezoelectric vibrator that saves power in comparison with the piezoelectric vibrator where the piezoelectric vibrating reed is bonded by soldering.

Further, the capacitance ratio γ affects the curve characteristic of a C_{L} curve (horizontal axis: C_{L}, vertical axis: Δf/f) shown in FIG. 17. As the capacitance ratio is increased, the CL curve rapidly approaches a horizontal line. That is, a CL curve may be changed from a CL curve (L1) shown by a solid line to a CL curve (L2) shown by a dotted line. Accordingly, since it is easy to make a CL curve be within a predetermined range (for example, ±20 ppm) of Δf/f, it may also be possible to achieve an advantage of easily manufacturing the piezoelectric vibrator.

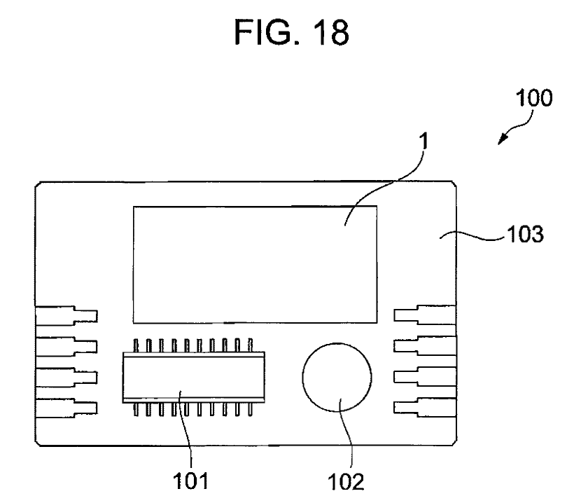

An embodiment of an oscillator according to the invention will be described below with reference to FIG. 18.

As shown in FIG. 18, an oscillator 100 according to this embodiment includes the piezoelectric vibrator 1 as an oscillating component that is electrically connected to an integrated circuit 101. The oscillator 100 includes a substrate 103 on which an electronic component 102 such as a capacitor is mounted. The integrated circuit 101 for the oscillator is mounted on the substrate 103, and the piezoelectric vibrating reed 4 of the piezoelectric vibrator 1 is mounted near the integrated circuit 101 on the substrate. The electronic component 102, the integrated circuit 101, and the piezoelectric vibrator 1 are electrically connected to one another by wiring patterns (not shown). Meanwhile, each of the components is molded with a resin (not shown).

When a voltage is applied to the piezoelectric vibrator 1 of the oscillator 100 having the above-mentioned structure, the piezoelectric vibrating reed 4 of the piezoelectric vibrator 1 vibrates. The vibration is converted into an electrical signal due to the piezoelectric characteristics of the piezoelectric vibrating reed 4, and is input to the integrated circuit 101 as an electrical signal. The input electrical signal is subjected to various processes by the integrated circuit 101 and is output as a frequency signal. Accordingly, the piezoelectric vibrator 1 functions as an oscillating component.

Further, by selectively setting the structure of the integrated circuit 101, for example, an RTC (real time clock) module and the like as needed, it is possible to add a function for controlling date or time of the operation of the device, an external device other than a single-function oscillator for a clock and the like, a function of providing time or a calendar.

As described above, the oscillator 100 according to this embodiment includes the piezoelectric vibrator 1 that is thinner and more compact than a piezoelectric vibrator in the related art. Accordingly, likewise, it may also be possible to make the oscillator 100 compact, and to meet a demand for the further reduction in size. In addition to this, it may be possible to obtain a stable and accurate frequency signal over a long period of time.

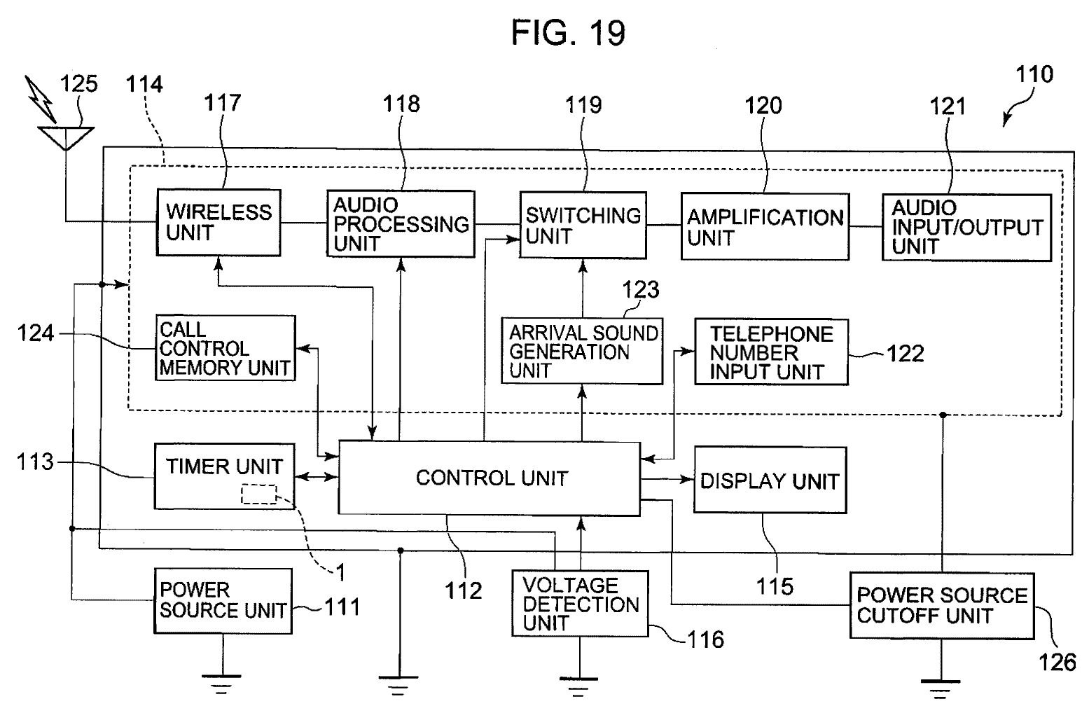

An embodiment of an electronic device according to the invention will be described with reference to FIG. 19. Meanwhile, a portable information terminal device 110 including the above-mentioned piezoelectric vibrator 1 will be exemplified as the electronic device. First, the portable information terminal device 110 according to this embodiment is typified by, for example, a cell phone, and is obtained by developing and improving a watch in the related art. The portable information terminal device is similar to a watch in appearance, a liquid crystal display is disposed at a portion of the portable information terminal device corresponding to a dial, and the portable information terminal device can display current time and the like on a screen of the liquid crystal display. Further, when the portable information terminal device is used as a communication device, the portable information terminal device may be used to perform communication like the cell phone in the related art through a speaker and a microphone that are built into an inner portion of a band after being separated from a wrist. However, the size and weight of the portable information terminal device are much smaller than those of the cell phone in the related art.

The structure of the portable information terminal device 110 according to this embodiment will be described below. As shown in FIG. 19, the portable information terminal device 110 includes the piezoelectric vibrator 1 and a power supply unit 111 for supplying power. The power supply unit 111 is formed of, for example, a lithium secondary battery. A control unit 112 that performs various kind of control, a clock unit 113 that counts time and the like, a communication unit 114 that communicates with the outside, a display unit 115 that displays various kinds of information, and a voltage detection unit 116 that detects voltages of the respective functional units are connected in parallel to the power supply unit 111. Further, power is supplied to each of the functional units by the power supply unit 111.

The control unit 112 controls the operation of the entire system, such as the transmission and reception of voice data and the measurement or display of the current time, by controlling the respective functional units. Further, the control unit 112 includes a ROM where programs are written in advance, a CPU that reads out and executes the programs written in the ROM, a RAM that is used as a work area of the CPU, and the like.

The clock unit 113 includes an integrated circuit and the piezoelectric vibrator 1. An oscillation circuit, a register circuit, a counter circuit, an interface circuit, and the like are built into the integrated circuit. When a voltage is applied to the piezoelectric vibrator 1, the piezoelectric vibrating reed 4 vibrates. The vibration is converted into an electrical signal due to the piezoelectric characteristics of crystal, and is input to the oscillation circuit as an electrical signal. The output of the oscillation circuit is binarized and counted by the register circuit and the counter circuit. Further, the clock unit transmits/receives a signal to/from the control unit 112 through the interface circuit. Current time, current date, calendar information, or the like is displayed on the display unit 115.

The communication unit 114 has the same function as the cell phone in the related art. The communication unit includes a wireless part 117, a voice processing part 118, a switching part 119, an amplifying part 120, a voice input/output part 121, a phone number input part 122, a ringtone generating part 123, and a call control memory part 124.

The wireless part 117 transmits/receives various data such as voice data to/from a base station through an antenna 125. The voice processing part 118 encodes and decodes a voice signal that is input from the wireless part 117 or the amplifying part 120. The amplifying part 120 amplifies a signal, which is input from the voice processing part 118 or the voice input/output part 121, up to a predetermined level. The voice input/output part 121 is formed of a speaker or a microphone or the like, and amplifies a ringtone or a received voice or collects a voice.

Further, the ringtone generating part 123 generates a ringtone in accordance with a call from a base station. The switching part 119 switches the amplifying part 120, which is connected to the voice processing part 118, to the ringtone generating part 123 when a call is received, so that the ringtone generated by the ringtone generating part 123 is output to the voice input/output part 121 through the amplifying part 120.

Meanwhile, the call control memory part 124 stores a program that is related to the outgoing/incoming call control of communication. Further, the phone number input part 122 includes number keys corresponding to, for example, 0 to 9 and other keys. When these number keys or the like are pressed down, the phone number of a callee is input.

When the voltage, which is applied to each functional unit such as the control unit 112 by the power supply unit 111, is lower than a predetermined value, the voltage detection unit 116 detects the voltage drop and notifies the control unit 112 of the voltage drop. The predetermined voltage value in this case is a value that is preset as the minimum voltage required for stably operating the communication unit 114, and is, for example, about 3 V. The control unit 112, which receives a notice of the voltage drop from the voltage detection unit 116, prohibits the operation of the wireless part 117, the voice processing part 118, the switching part 119, and the ringtone generating part 123. In particular, it is essential to stop the operation of the wireless part 117 with large power consumption. Further, a message that the communication unit 114 is not available due to the lack of the battery power is displayed on the display unit 115.

That is, the operation of the communication unit 114 is prohibited by the voltage detection unit 116 and the control unit 112, and a message that the operation of the communication unit is prohibited by the voltage detection unit and the control unit may be displayed on the display unit 115. The display may be a short message. However, an “x” (cross) mark may be displayed at a phone icon, which is displayed at an upper portion on the display screen of the display unit 115, as an intuitive display.

Meanwhile, if there is provided a power cutting-off unit 126 that can selectively cut off power applied to parts related to a function of the communication unit 114, it may be possible to more reliably stop the function of the communication unit 114.

As described above, the portable information terminal device 110 according to this embodiment includes the piezoelectric vibrator 1 that is thinner and more compact than a piezoelectric vibrator in the related art. Accordingly, likewise, it may also be possible to make the portable information terminal device compact, and to meet a demand for the further reduction in size. In addition to this, it may be possible to display stable and accurate clock information over a long period of time.

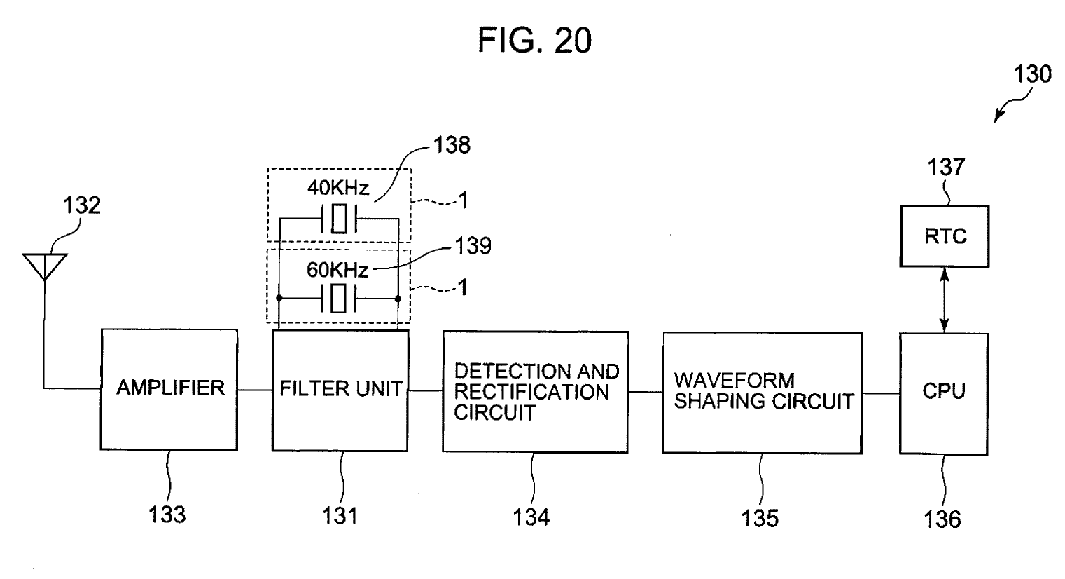

An embodiment of a radio clock according to the invention will be described with reference to FIG. 20.

As shown in FIG. 20, a radio clock 130 according to this embodiment includes the piezoelectric vibrator 1 that is electrically connected to a filter unit 131. The radio clock is a clock that has a function of receiving standard waves including clock information, a function of automatically correcting the standard waves at a correct time, and a function of displaying the standard waves.

In Japan, transmission stations (transmitter station) for transmitting standard waves are located in Fukushima Prefecture (40 kHz) and Saga Prefecture (60 kHz) and transmit standard waves. A long wave corresponding to 40 kHz or 60 kHz has both a property of propagating on the surface of the ground and a property of propagating while the long wave is reflected from an ionization layer and the surface of the ground. Accordingly, the propagation range of the long wave is wide, and the above-mentioned two transmission stations cover the entire area of Japan.

The functional structure of the radio clock 130 will be described in detail below.

An antenna 132 receives standard waves that are long waves corresponding to 40 kHz or 60 kHz. The standard wave, which is a long wave, is a wave that is obtained by performing AM modulation of time information, which is called time codes, in a carrier wave corresponding to 40 kHz or 60 kHz. The reception standard wave, which is a long wave, is amplified by the amplifier 133, and is filtered and synchronized by the filter unit 131 including a plurality of piezoelectric vibrators 1.

The piezoelectric vibrators 1 of this embodiment include crystal vibrator parts 138 and 139 having resonant frequencies of 40 kHz and 60 kHz, which are equal to the carrier frequencies, respectively.

Further, the filtered signal having a predetermined frequency is detected and demodulated by a detection/rectification circuit 134. Subsequently, the time codes are extracted through a wave-shaping circuit 135, and are counted by a CPU 136. The CPU 136 reads out information, such as the current year, accumulated days, a day of the week, and time. The read information is reflected in the RTC 137, so that correct time information is displayed.

Since the carrier wave corresponds to 40 kHz or 60 kHz, a vibrator having the above-mentioned tuning-fork type structure is preferably used as each of the crystal vibrator parts 138 and 139.

Meanwhile, the case of Japan has been exemplified above, but the frequency of the standard wave, which is a long wave, varies abroad. For example, a standard wave corresponding to 77.5 KHz is used in Germany. Accordingly, when a radio clock 130, which can also be used abroad, is to be built into a portable device, there is needed a piezoelectric vibrator 1 having a frequency different from a frequency of the case of Japan.

As described above, the radio clock 130 according to this embodiment includes the piezoelectric vibrator 1 that is thinner and more compact than a piezoelectric vibrator in the related art. Accordingly, likewise, it may also be possible to make the radio clock compact, and to meet a demand for the further reduction in size. In addition to this, it may be possible to stably and accurately count time over a long period of time.

Meanwhile, the technical scope of the invention is not limited to the above-mentioned embodiments, and various modifications may be made to the invention without departing from the scope of the invention.

For example, in the above-mentioned embodiment, a grooved piezoelectric vibrating reed where the groove portions 18 are formed on both surfaces of the vibration arm portions 10 and 11 has been described as an example of the piezoelectric vibrating reed 4. Meanwhile, a piezoelectric vibrating reed without the groove portions 18 may be used. However, if the groove portions 18 are formed, it may be improve electric field efficiency between the pair of excitation electrodes 15 when a predetermined voltage is applied to the pair of excitation electrodes 15. Accordingly, it may be possible to further suppress vibration loss and to further improve vibration characteristics. That is, it may be possible to further lower a CI value (crystal Impedance) and to further improve the performance of the piezoelectric vibrating reed 4. In this regard, it is preferable to form the groove portions 18.

Further, the tuning-fork type piezoelectric vibrating reed 4 has been exemplified in the above-mentioned embodiment, but the piezoelectric vibrating reed is not limited to a tuning-fork type piezoelectric vibrating reed. For example, a thickness-shear vibrating reed may be used.

Further, the piezoelectric vibrating reed 4 has been bonded by using the bumps in each of the above-mentioned embodiments, but a method of bonding the piezoelectric vibrating reed is not limited to bump bonding.

Furthermore, there has been described a case where the base substrate 2 and the lid substrate 3 are anodically bonded to each other, but a bonding method is not limited to anodic bonding. For example, the base substrate 2 and the lid substrate 3 may be bonded to each other by using gold-tin solder. In this case, in a bonding process, the base substrate wafer 40 and the lid substrate wafer 50 may be bonded to each other by gold-tin solder.

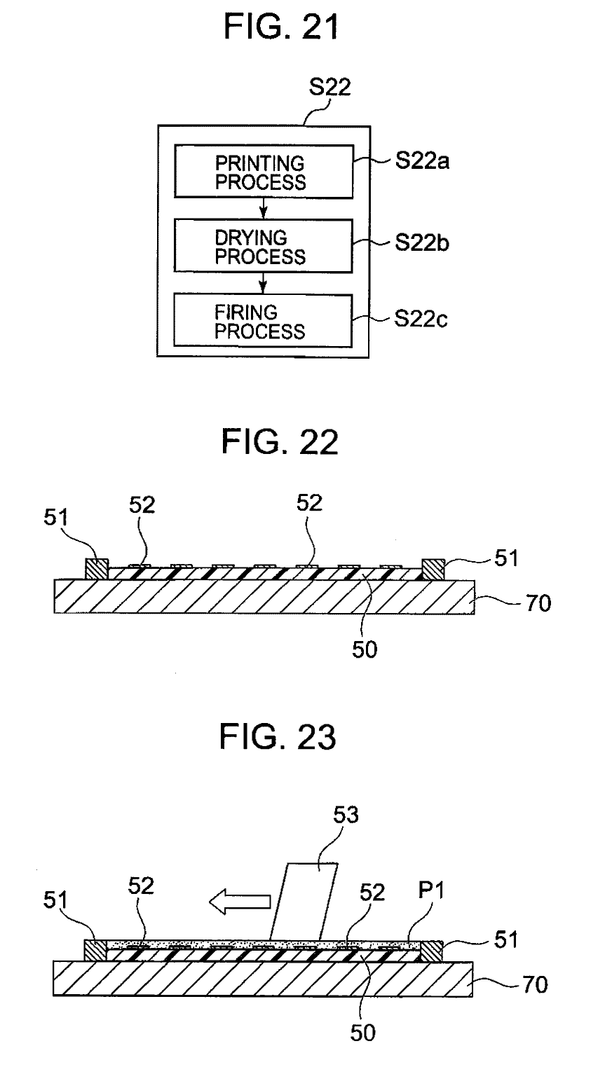

Further, in the above-mentioned embodiment, the recesses have been formed by etching and the like when a recess forming process for forming the recesses 3a for cavities on the lid substrate wafer 50 is performed. However, the recesses 3a may be formed without cutting. For example, the recesses 3a may be formed by the screen printing of glass paste P1. In this case, as shown in FIG. 21, a printing process S22a, a drying process S22b, and a firing process S22c may be performed during the recess forming process S22. Each of these processes will be described in detail.

First, as shown in FIG. 22, the lid substrate wafers 50 on which cleaning and the like has been completed are placed on wafer fixing plates 70, and the periphery of each of the lid substrate wafers is fixed by a fixing jig 51. Further, a printing mask 52 serving as a screen is set on the surface of the fixed lid substrate wafer 50. The printing mask 52 is a mask that is disposed so as to cover areas which later form recesses 3a, and the thickness of the printing mask is in the range of about 50 to 200 μm.

Subsequently, as shown in FIG. 23, glass paste P1 serving as printing ink is supplied on the surface of the lid substrate wafer 50. Then, a squeegee 53 is moved to expand all of the paste P1 while pressing it. Accordingly, the paste P1 is pushed out to unmasked areas, so that screen printing is performed on the unmasked areas of the lid substrate wafer 50. That is, it may be possible to perform screen printing while patterning is performed so that the glass paste P1 surrounds the portions forming recesses 3a. Accordingly, the printing process S22a is completed. Meanwhile, the thickness of the paste P1, which is printed once, is equal to the thickness of the printing mask 52.

Subsequently, there is performed a drying process S22b for drying the printed glass paste P1. For example, the respective wafer fixing plates 70 are put into a furnace and the paste is dried at a temperature of 100° C. for about 30 minutes. As a result, the glass paste P1, which was previously printed, is in a dried state.

Further, the above-mentioned printing process S22a is performed again, so that the glass paste P1 is newly applied on the dried paste P1 by screen printing. After that, the drying process S22b is performed again, so that the new paste P1 is dried.

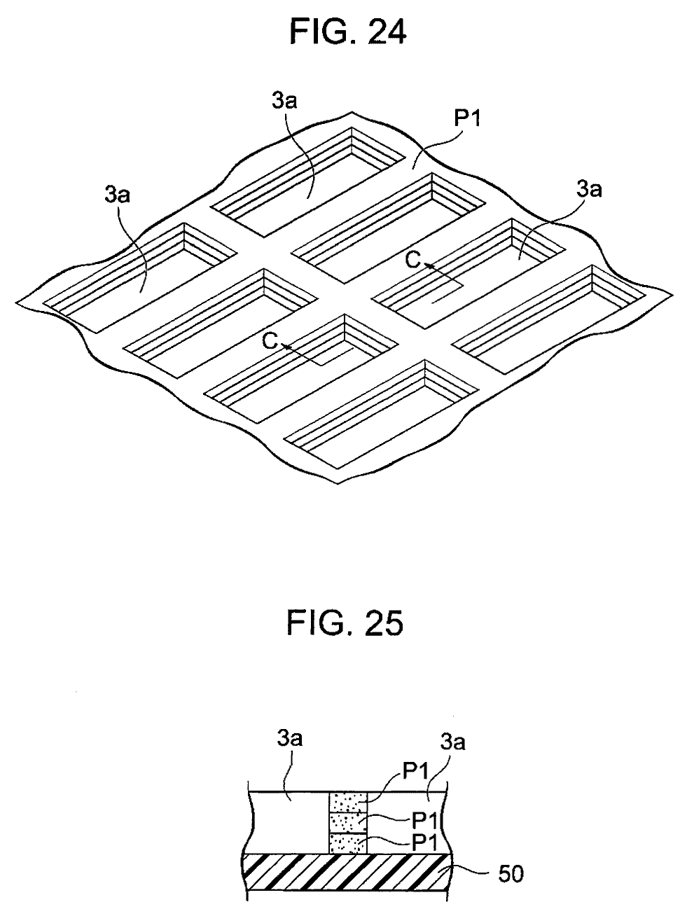

Further, as shown in FIGS. 24 and 25, the printing process S22a and the drying process S22b are repeatedly performed several times until the recesses 3a are formed by the application of the paste P1. Meanwhile, FIGS. 24 and 25 show the recesses 3a that are formed by performing the printing process S22a and the drying process S22b three times. That is, the total height of the applied paste P1 is 150 μm when the thickness of the printing mask 52 is 50 μm. Further, the above-mentioned 150 μm is the depth of the recess 3a.

Furthermore, after the recesses 3a are formed by the application of the paste P1, there is performed a firing process S22c for completely hardening the paste by firing the applied and dried paste P1. Accordingly, the applied paste P1 and the lid substrate wafer 50 are integrated with each other.

As a result, it may be possible to form the recesses 3a on the lid substrate wafer 50 without cutting such as etching. In particular, since it is not necessary to cut the lid substrate wafer 50, it may be possible to reduce the load to be applied to the wafer 50 and to achieve an improvement in the quality of the piezoelectric vibrator 1. Meanwhile, the thickness of the printing mask 52, the number of times of printing, and the like may be freely set.

Further, in the above-mentioned embodiment, mechanical drilling, laser beam machining, and sandblasting may be used to form through holes at the base substrate wafer 40. In this case, drilling and laser beam machining may be employed to form straight through holes, and sandblasting may be employed to form tapered through holes.

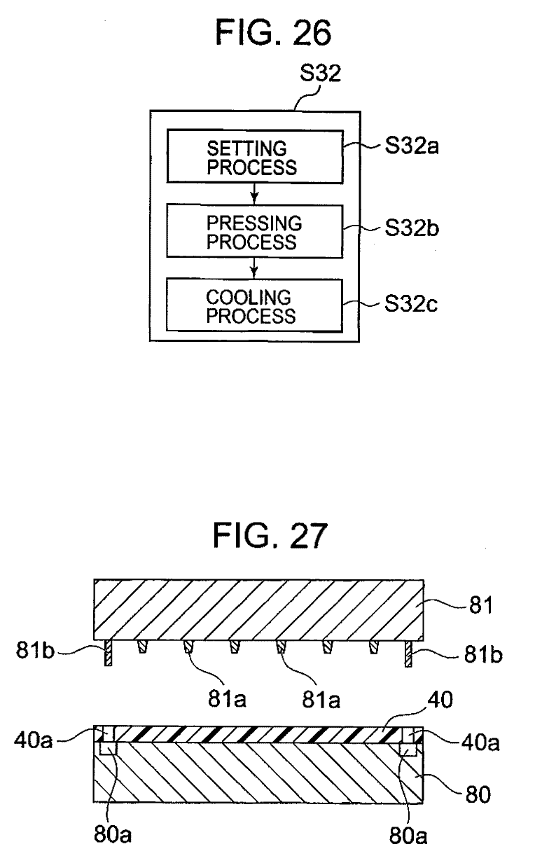

In particular, it is preferable that a pressing method using a die be used as a method of simply and reliably forming through holes. In this case, as shown in FIG. 26, a setting process 32a, a pressing process 32b, and a cooling process 32c may be performed during the through hole forming process S32. Each of these processes will be described in detail.

Further, there is performed a setting process 32a for setting the base substrate wafer 40, on which cleaning and the like has been completed, between a lower die 80 and an upper die 81 that includes pins 81a protruding toward the lower die 80, as shown in FIG. 27. Meanwhile, the pin 81a is formed in a tapered shape so that the diameter of the pin is gradually decreased toward the tip. Further, positioning pins 81b, which are to be inserted into positioning holes 80a formed at the lower die 80, are fixed to the upper die 81 independently of the pins 81a. Further, insertion holes 40a, into which the positioning pins 81b are inserted, are formed at the base substrate wafer 40 before the setting process 32a, and the base substrate wafer is set so that the insertion holes 40a correspond to the positioning holes 80a.

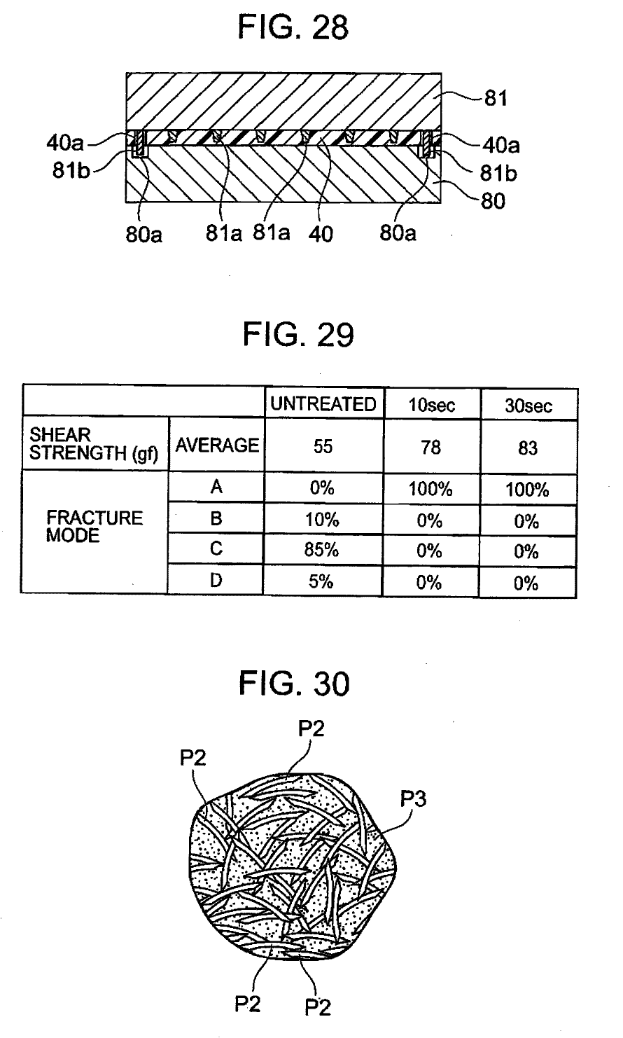

Subsequently, all the wafer fixing plates are put into the furnace, and the base substrate wafers 40 are heated up to a predetermined temperature (a temperature equal to or higher than a glass softening point). Further, there is performed a pressing process 32b for pressing the base substrate wafer by the lower and upper dies 80 and 81 and forming through holes at the base substrate wafer 40 by the pins 81a of the upper die 81 as shown in FIG. 28. In this case, the positioning pins 81a of the upper die 81 are inserted into the insertion holes 40a of the base substrate wafer 40 and the positioning holes 80a of the lower die 80. Accordingly, since the lower and upper dies 80 and 81 and the base substrate wafer 40 are reliably positioned, it may be possible to accurately form through holes at desired positions. Further, finally, there is performed a cooling process 32c for cooling and solidifying the base substrate wafer 40. Accordingly, the through hole forming process S32 is completed.

In particular, since it may be possible to form through holes at a time by a simple method, that is, only by performing the pressing with dies, it may be possible to improve manufacturing efficiency. In addition, it may be possible to form tapered through holes.

Meanwhile, it is preferable that the wafer 40, which has a circular shape in plan view as described above, be used to form through holes by pressing the dies. That is, if the base substrate wafer 40 has a circular shape, the base substrate wafer is hardly deformed even though thermal expansion and thermal contraction occur on the wafer due to the heating caused by the pressing process 32b and the cooling caused by the cooling process 32c. Accordingly, it may be possible to maintain a high level of accuracy of dimension and thickness.

If a wafer has a substantially rectangular shape in plan view (for example, substantially oblong shape in plan view), there is a concern that the wafer is deformed when the wafer expands and contracts due to heating and cooling. For this reason, the accuracy of dimension and thickness is lowered. Since the wafer has corners, stress is apt to be concentrated near the corners during the expansion. For this reason, an expansion state and a contraction state become non-uniform. Accordingly, it is considered that the wafer is difficult to return to its original state. Further, if a wafer having a substantially rectangular shape in plan view is used, the accuracy of dimension and thickness is lowered and an expansion state and a contraction state become non-uniform, so that excessive loads are applied to the pins 81a. For this reason, there has been a possibility that the pins 81a are deformed or bent.

However, since a circular wafer without corners is used, there is less concern that the above-mentioned problems are generated even though through holes are formed by a press work accompanying with heating and cooling. Meanwhile, the both surfaces of the base substrate wafer 40 may be polished after the cooling process 32c. Accordingly, it may be possible to more reliably form the through holes.

Further, in the above-mentioned embodiment, it is preferable to perform a cleaning treatment by applying plasma (for example, oxygen plasma) to the routing electrodes 36 and 37 for at least 10 seconds before the bumps B are formed on the routing electrodes 36 and 37. Accordingly, it may be possible to remove sources of pollution such as dust, to clean the surface on which the bumps B are to be formed, and to modify the surface. In particular, since plasma is applied for at least 10 seconds, it may be possible to reliably remove sources of pollution so that the pollution does not remain. Accordingly, it may be possible to improve a contact property and an adhesive property between the routing electrode and the bump B, and to increase the resistance of the bump B to shear peeling. For this reason, it may be possible to improve the mounting performance of the piezoelectric vibrating reed 4. As a result, it may be possible to improve the quality of the piezoelectric vibrator 1.

Here, FIG. 29 shows the results of an actual scratch test of the bumps B when the bumps B are formed without a plasma cleaning treatment and when the bumps B are formed after a plasma cleaning process.

Meanwhile, the test with the plasma cleaning treatment included two cases, that is, a case where plasma was applied for 10 seconds and a case where plasma was applied for 30 seconds. Further, the scratch test was performed 100 times in both cases. Furthermore, the scratch strength of the bump B, that is, the shear strength of the bump was 55 (gf) on the average when a plasma cleaning treatment was not performed, 78 (gf) on the average when plasma was applied for 10 seconds, and 83 (gf) on the average when plasma was applied for 30 seconds.

Moreover, a fracture mode A means that the bump B remains in a substantially complete form without being removed after the scratch test. A fracture mode B means that the bump B is slightly removed but most of the bump B remains after the scratch test. A fracture mode C means that most of the bump B is removed and a part of the bump B slightly remains after the scratch test. A fracture mode D means that the bump B is completely removed after the scratch test.

As shown in FIG. 29, first, as a result of a scratch test of the bump B that was formed without a plasma cleaning treatment, 85% of the bumps corresponded to the fracture mode C and 0% of the bumps corresponded to the fracture mode A. In contrast, as a result of a scratch test of the bump B that was formed after a plasma cleaning treatment, 100% of the bumps, which were formed when plasma was applied for 10 and 30 seconds, corresponded to the fracture mode A. In addition, all bumps corresponded to the fracture mode A regardless of the magnitude of scratch strength (shear strength).

As described above, it was possible to actually confirm that the shear peeling strength of the bump B was improved by forming the bump B after a plasma cleaning treatment. Further, it was possible to actually confirm that a sufficient effect was exerted by applying plasma for at least 10 seconds.

Furthermore, in the above-mentioned embodiment, it is preferable to perform a surface machining process that makes the arithmetic mean roughness (Ra) be 10 nm or less by machining the upper surface of the base substrate wafer 40 before the formation of the bumps B. For example, there are mirror polishing such as polishing, surface grinding performed by a grinder, and the like as a method of machining the surface. In any methods, it may be possible to make the upper surface of the base substrate wafer 40, which is a base on which the bumps B are formed, be as close as possible to a flat and smooth surface by machining the surface. For this reason, it may also be possible to improve a contact property and an adhesive property between the routing electrode and the bump B, and to increase the resistance of the bump to shear peeling. Accordingly, it may be possible to improve the mounting performance of the piezoelectric vibrating reed 4 even by this method. As a result, it may be possible to improve the quality of the piezoelectric vibrator 1.

In particular, it may be possible to further improve by the combination of this method and the above-mentioned plasma cleaning treatment, which is preferable.

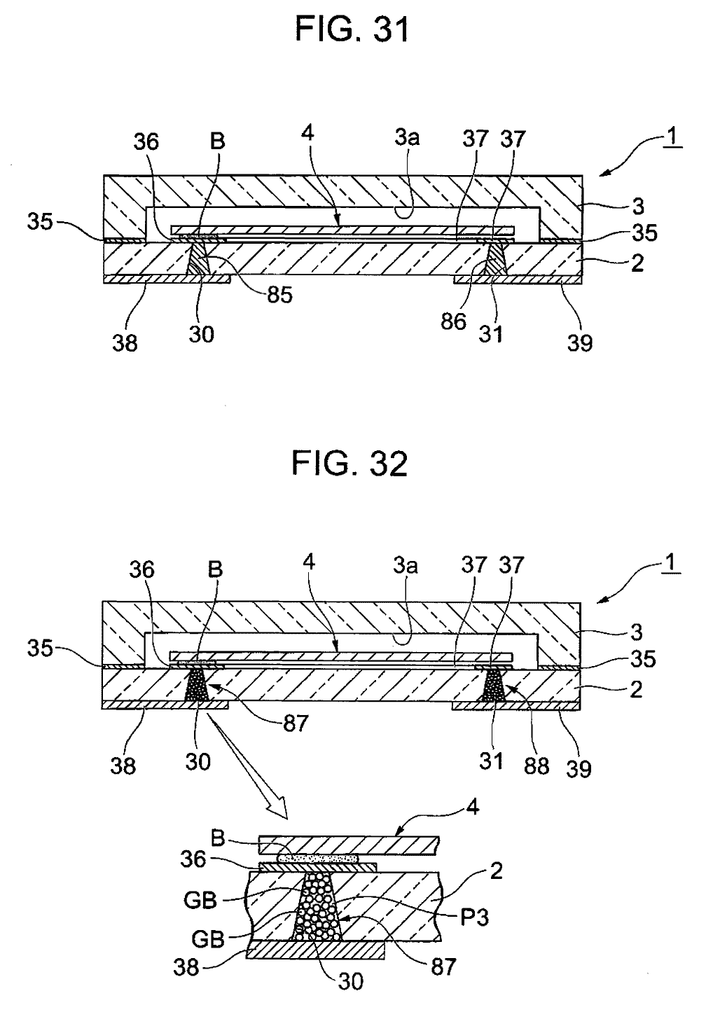

Further, in the above-mentioned embodiment, the through electrodes 32 and 33 have been formed by filling the through holes 30 and 31 with a conductive material (not shown). However, as shown in FIG. 31, through electrodes 85 and 86 may be formed by filling the through holes 30 and 31 with paste P3 that contains a plurality of metal fine particles P2 shown in FIG. 30 and hardening the paste P3. In this case, the plurality of metal fine particles P2 contained in the paste P3 come into contact with each other, so that the electric conductivity of the through electrodes 85 and 86 is secured. Accordingly, it may be possible to make the through electrodes reliably function as electrodes.

Here, in order to form the through electrodes 85 and 86 by using the paste P3, the through electrode forming process S33 may be performed as follows:

First, there is performed a filling process for closing the through holes 30 and 31 by filling the through holes 30 and 31 with the paste P3 containing the metal fine particles P2 without leaving any spaces. Subsequently, there is performed a firing process for hardening the filled paste P3 by firing the filled paste at a predetermined temperature. As a result, the paste P3 is solidly fixed to the inner surfaces of the through holes 30 and 31. Meanwhile, since organic materials (not shown) in the paste P3 are evaporated during the firing, the volume of the hardened paste P3 decreases in comparison with the volume of the paste in the filling process. For this reason, recesses are necessarily formed on the surface of the paste P3.

Then, there is performed a polishing process for polishing both surfaces of the base substrate wafer 40 by a predetermined thickness after the firing. Since both surfaces of the paste P3, which has been hardened by firing, may be simultaneously polished by this process, it may be possible to scrape the peripheral portions of the recesses. That is, it may be possible to make the surfaces of the paste P3 flat. Accordingly, it may be possible to make the surfaces of the base substrate wafer 40 be substantially flush with the surfaces of the through electrodes 85 and 86. The through electrode forming process is completed by performing the polishing process.

As a result, it may be possible to form the through electrodes 85 and 86 by the paste P3. Meanwhile, the tapered through holes 30 and 31 are exemplified in FIG. 31. In this case, a sandblasting method or a pressing method using a die may be used to form the through holes 30 and 31.

Further, when the through electrodes are formed using the paste P3, it may be possible to form through electrodes 87 and 88 by hardening the paste P3 containing a plurality of glass beads GB as shown in FIG. 32. Since the amount of the paste P3 may be reduced by the glass beads GB in this case, it may be possible to reduce the amount of the organic materials that are decreased by the firing. Accordingly, it may be possible to reduce the recesses, which are formed on the surface of the paste after the hardening of the paste P3, to a negligibly small size. Therefore, there is an advantage of omitting the polishing process.

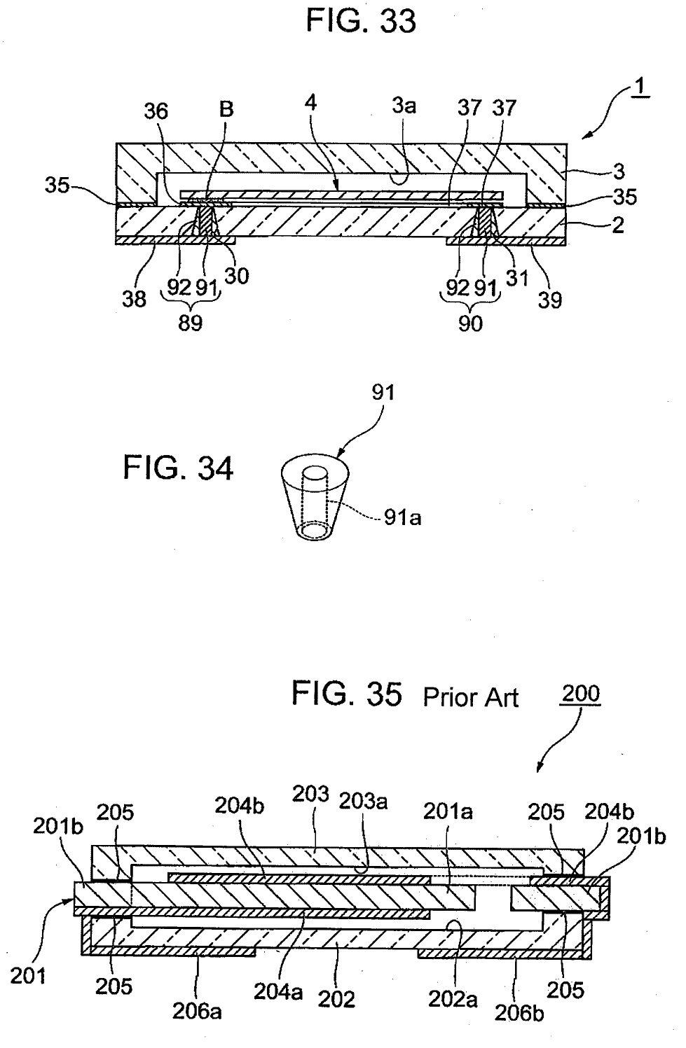

Further, as another example of the through electrode, as shown in FIG. 33, through electrodes 89 and 90 may include cylindrical bodies 91 that are fitted to the through holes 30 and 31 and conductive core members 92 that are inserted into center holes 91a of the cylindrical bodies 91 and fixed integrally with the cylindrical bodies by firing. Meanwhile, the tapered through holes 30 and 31 are exemplified even in FIG. 33.

A through electrode forming process in this case may be performed as follows:

First, there is performed a setting process for fitting the cylindrical bodies 91 to the through holes 30 and 31 and inserting the core members 92 into the center holes 91a of the cylindrical bodies 91. Meanwhile, as the cylindrical body 91, there is used a cylindrical body, which is made of the same glass material as that of the base substrate 2, is temporarily fired in advance, is formed to have both ends flat and is formed substantially in the shape of a cylinder having substantially the same thickness as the thickness of the base substrate 2 as shown in FIG. 34. In addition, there are used cylindrical bodies that have center holes 91a, which pass through the cylindrical bodies 91, at the center thereof and are formed to have a conical shape (a tapered shape in cross section) that corresponds to the through holes 30 and 31. Meanwhile, the core member 92 is a conductive core member that is made of a metal material and is formed in a cylindrical shape as shown in FIG. 33. A core member, which has substantially the same thickness as the thickness of the base substrate 2 like the cylindrical body 91, is used as the core member.

Further, after the setting process is completed, there is performed a firing process for firing the fitted cylindrical body 91 at a predetermined temperature. Accordingly, it may be possible to integrally fix the through holes 30 and 31, the cylindrical bodies 91, and the core members 92. Therefore, it may be possible to form the through electrodes 89 and 90, and the through electrode forming process is completed.

In particular, since the glass cylindrical body 91 and not the paste P3 is used, the volume of the cylindrical body 91 is hardly reduced after firing and recesses are hardly formed on the surface. Accordingly, it may also be possible to form the through electrodes 89 and 90 without a polishing process

1. A method for producing piezoelectric vibrators, comprising:
(a) defining a plurality of first substrates on a first wafer and a plurality of second substrates on a second wafer;
(b) forming a recess in respective at least some of at least one of the first substrates and the second substrates to create a cavity between the first and second substrates;
(c) forming at least one through-hole in respective at least some of the first substrates;
(d) forming a conductive path in respective at least some of the through-holes;
(e) forming conductive patterns on respective at least some of the first substrates;
(f) mounting a piezoelectric vibrating strip in contact with the conductive patterns on respective at least some of the first substrates;
(g) layering the first and second wafers such that at least some of the first substrates substantially coincide respectively with at least some of the corresponding second substrates, wherein the piezoelectric vibrating strip is secured in the cavity in respective pairs of at least some of coinciding first and second substrates;
(h) hermetically bonding the first and second substrates of at least some of the respective pairs;
(i) cutting off respective at least some of the hermetically bonded pairs from the first and second wafers.

2. The method according to claim 1, wherein mounting a piezoelectric vibrating strip in contact with the conductive patterns comprises forming bumps on the conductive patterns and bonding the piezoelectric vibrating strip to the bumps.

3. The method according to claim 2, wherein forming bumps on the conductive patterns comprises treating the conductive patterns by plasma cleaning before forming the bumps.

4. The method according to claim 3, wherein the plasma cleaning is performed for about 10 seconds.

5. The method according to claim 2, wherein forming bumps on the conductive patterns comprises, before forming the bumps, providing an arithmetic mean roughness of 10 nm or less to a surface of the first substrate on which the piezoelectric vibrating strip is mounted.

6. The method according to claim 5, wherein providing an arithmetic mean roughness of 10 nm or less to a surface of the first substrate comprises subjecting the surface to one of polishing and grinding.

7. The method according to claim 1, wherein hermetically bonding the first and second substrates comprises anodically bonding the first and second substrates.

8. The method according to claim 1, wherein forming a recess in respective at least some of at least one of the first substrates and the second substrates comprises screen-printing at least one tier of paste on respective at least some of at least one of the first substrates and the second substrates.

9. The method according to claim 1, wherein forming at least one through-hole in respective at least some of the first substrates comprises press-forming at least one through-hole at once in respective at least some of the first substrates.

10. The method according to claim 9, wherein press-forming at least one through-hole at once in respective at least some of the first substrates comprises heating the first wafer and pressing the first wafer with a presser having a plurality of projections.

11. The method according to claim 1, wherein the at least one of the first and second wafers is in a shape of circular disk.

12. The method according to claim 1, wherein forming at least one through-hole in respective at least some of the first substrates comprises forming at least one through-hole each configured to go larger in cross-section from an inner surface of the first substrate towards an outer surface thereof.

13. The method according to claim 1, wherein forming a conductive path in respective at least some of the through-holes comprises filling respective at least some of the through-holes with conductive paste and firing the conductive paste to solidify it.

14. The method according to claim 1, wherein forming a conductive path in respective at least some of the through-holes comprises filling respective at least some of the through-holes with conductive beads mixed with conductive binder paste and firing the paste to solidify it.

15. The method according to claim 1, wherein forming a conductive path in respective at least some of the through-holes comprises filling respective at least some of the through-holes with a plug having a conductive material going through the plug.

16. The method according to claim 1, wherein the plug is made of a same material as the first substrates.

17. A piezoelectric vibrator comprising:
a hermetically closed casing comprising first and second substrates with a cavity inside, the first substrate being formed with at least one through-hole;
a conductive path formed in the respective through-holes; and
a piezoelectric vibrating strip secured inside the cavity and electrically connected via conductive patterns to the conductive paths in the through-holes.

18. The piezoelectric vibrator according to claim 17, further comprising a bonding layer between the first and second substrates for anodically bonding the first and second substrates.

19. The piezoelectric vibrator according to claim 17, further comprising bumps formed on the conductive patters, and the piezoelectric vibrating strip is bonded to the bumps.

20. The piezoelectric vibrator according to claim 19, wherein the conductive patterns have surfaces treated by plasma cleaning for forming the bumps thereon.

21. The piezoelectric vibrator according to claim 17, wherein the first substrate has a surface flattened to an arithmetic mean roughness of 10 nm or less for mounting the piezoelectric vibrating strip thereon.

22. The piezoelectric vibrator according to claim 17, wherein at least one of the first and second substrates comprises at least one tier of screen-printed paste to form the cavity between the closed first and second substrates.

23. The piezoelectric vibrator according to claim 17, wherein the pair of through-holes are press-formed through-holes in the first substrate.

24. The piezoelectric vibrator according to claim 17, wherein the pair of through-holes are each configured to go larger in cross-section from an inner surface of the first substrate towards an outer surface thereof.

25. The piezoelectric vibrator according to claim 17, wherein the conductive paths are formed with fire-solidified conductive paste.

26. The piezoelectric vibrator according to claim 17, wherein the conductive paths are formed with conductive beads mixed with fire-solidified conductive binder paste.

27. The piezoelectric vibrator according to claim 17, wherein the conductive paths are each formed with a plug having a conductive material going through the plug.

28. The piezoelectric vibrator according to claim 27, wherein the plug is made of a same material as the first substrates.

29. An oscillator comprising the piezoelectric vibrator defined in claim 17.

30. An electronic device comprising the piezoelectric vibrator defined in claim 17.

31. The electronic device according to claim 30, wherein the electronic device is an atomic clock.
